(19) United States
(12) Patent Application Publication
(10) Pub. No.: US 2021/0117582 A1
(43) Pub. Date: Apr. 22, 2021

(54) Visualizing Building Interior Information In A User-Customized Manner

(71) Applicant: Select Interior Concepts, Inc., Atlanta, GA (US)

(72) Inventors: Jennifer Kamenca, Huntington Beach, CA (US); Elliot Litz, Golden, CO (US)

(21) Appl. No.: 17/071,856

(22) Filed: Oct. 15, 2020

Related U.S. Application Data
(60) Provisional application No. 62/915,954, filed on Oct. 16, 2019.

(51) Int. Cl. G06F 30/12; G06F 30/13

(52) U.S. Cl. CPC G06F 30/12; G06F 30/13

(57) ABSTRACT

Techniques are described for using one or more computing devices to perform automated operations related to presenting simulated visualizations of building interior information in a user-customized manner. In at least some situations, the building is a house, and the described techniques include providing a graphical user interface (GUI) that is displayed on a client computing device to an end-user (e.g., as part of a provided Web site), and via which the end-user may customize at least some aspects of the building interior in accordance with defined constraints, such as partner-defined constraints that are specified by a partner entity associated with the house, and/or system-defined constraints that are specified by an operator of the system providing the GUI. Various additional associated functionality and information may be provided in at least some embodiments, including to generate and provide information associated with a particular customization created by a particular end-user.

### CROSS REFERENCE TO RELATED APPLICATIONS

This application claims the benefit of U.S. Provisional Patent Application No. 62/915,954, filed Oct. 16, 2019 and entitled “Visualizing Building Interior Information In A User-Customized Manner,” which is hereby incorporated by reference in its entirety.

### TECHNICAL FIELD

The following disclosure relates generally to techniques for providing simulated visual information for a building interior along with associated functionality, such as to present photo-realistic simulated visualizations of building interior information in a manner that is user-customized and uses defined constraints, and to generate and provide additional associated information and functionality.

### BACKGROUND

In various fields and circumstances, such as architectural analysis, real estate acquisition and development, remodeling and improvement services, general contracting and other circumstances, it may be desirable to view information about the interior of a house, office, or other building, including for buildings that are under construction or not yet built, as well as for existing buildings in order to eliminate a need to physically travel to and enter such existing buildings. However, it can be difficult or impossible to effectively display visual information about building interiors to users at remote locations, such as to enable a user to fully understand the layout and other details of the interior, including under varying conditions.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a network diagram illustrating an example environment in which a system for performing at least some of the described techniques may operate.

FIGS. 2A-2R illustrate examples of automated operations for presenting simulated visualizations of building interior information in a manner that is user-customized and uses defined constraints, and for generating and providing additional associated information.

FIG. 3 is a block diagram illustrating computing systems suitable for executing embodiments of one or more systems that perform at least some of the techniques described in the present disclosure.

FIGS. 4A-4C illustrate an example embodiment of a flow diagram for a Building Interior Visualizer (BIV) system routine in accordance with an embodiment of the present disclosure.

FIG. 5 illustrates an example embodiment of a flow diagram for a Client System routine in accordance with an embodiment of the present disclosure.

### DETAILED DESCRIPTION

The present disclosure describes techniques for using one or more computing devices to perform automated operations related to presenting simulated visualizations of building interior information in a user-customized manner. In at least some embodiments, the building is a house, and the described techniques include providing a graphical user interface (GUI) that is displayed on a client computing device to an end-user (e.g., as part of a provided Web site), and via which the end-user may customize at least some aspects of the house's interior in accordance with defined constraints, such as partner-defined constraints that are specified by a partner entity associated with the house, and/or system-defined constraints that are specified by an operator of the system providing the GUI (e.g., to reflect physical constraints on particular types of interior aspects). Various additional associated functionality and information may be provided in at least some embodiments, including to generate and provide information associated with a particular group of one or more customizations created by a particular end-user. Additional details are included below regarding the automated operations of the computing device(s) involved in the presenting of simulated building interior visualizations and the providing of associated functionality, and some or all of the techniques described herein may, in at least some embodiments, be performed at least in part via automated operations of a Building Interior Visualizer (“BIV”) system, as discussed further below.

The automated presentation of simulated building interior visualizations based on end-user customizations may be performed in various manners in various embodiments, and in at least some embodiments, the end-user customizations and associated visualizations for a building's interior are based in part on starting with a floor plan for the building, and adding and using defined constraints that affect the end-user customizations and/or associated visualizations for the building. Such defined constraints associated with a building's floor plan may include, for example, definitions of particular surfaces in the interior and/or other interior elements that are available for customization, such as one or more of the following: some or all floors (e.g., for specified rooms, for specified areas within rooms or across rooms, etc., and with respect to floor types and/or coverings such as hard wood, tile, concrete, carpet, linoleum, etc.), some or all countertops (e.g., for kitchen counters, for bathroom counters, etc.), some or all walls (e.g., for wall paper, paint or other wall coverings), some or all ceilings, some or all internal structures other than walls (e.g., a kitchen island, sink, shower/bath, fireplace, cabinet, window, door, stairs, a built-in piece of furniture, etc.); some or all appliances and/or fixtures (e.g., kitchen appliances, plumbing fixtures, lighting fixtures, ceiling fans, etc.) and other interior elements (e.g., curtains, blinds, etc.); some or all patterns or layouts of materials and/or associated installation techniques; etc. Such defined constraints may further include restrictions on types of customizations for particular defined surfaces or other interior elements, such as to provide an enumerated list of candidate options that are allowed for a particular type of customization, or to otherwise specify criteria that some or all customizations are to satisfy (e.g., a minimum and/or maximum quantity of customizations, a minimum and/or maximum cost associated with customizations, etc.). Such defined constraints may further include associations and restrictions between different defined surfaces or other interior elements, such as to associate the floors in multiple defined rooms (e.g., such that they all have the same floor type and/or floor covering, or that they all have different floor types and/or floor coverings), to associate one or more floors with one or more other surfaces (e.g., a tile floor in one room is to use the same tile as a countertop in another room or is to use a different tile than the countertop), to associate multiple walls and/or ceilings (e.g., that they all have the same paint or other covering, or that they all have different coverings), etc. Such defined constraints may further include additional restrictions for a particular type of customization and/or between multiple customizations, or may otherwise group or package multiple products or other candidate options together as a single candidate option to be used together (e.g., for an end-user to select between multiple alternative such defined groups/packages), such as that a specified type of paint also has an associated type of primer, a specified type and/or layout of tile also has one or more associated additional types of tile pieces, a specified material cannot be used in a specified location or other environment, etc. In addition, such constraints may be specified in various manners in various embodiments and situations, such as for some or all of the constraints to be specified by a partner entity associated with a building (e.g., a builder who constructs the building, an owner or other entity who sells the building, a remodeler who remodels or otherwise modifies an existing building, an organization to which an end-user belongs, etc.), such as before end-user customizations for the building are initiated, and/or for some or all of the constraints to be specified by an operator of the BIV system (e.g., restrictions for certain types of customizations, such as based on physical properties of materials used for the customizations). Additional details are included below regarding the definition and use of constraints on an end-user's customizations of a building's interior.

In addition, a floor plan and/or additional associated information may be used to produce a simulated visualization of a building interior, such as to render a photo-realistic simulated visualization of one or more rooms in the floor plan (or portions of one or more rooms) in accordance with any end-user customizations that correspond to the rooms (or room portions). In some embodiments, a Room Visualization Generation (RVG) system performs some or all such simulated building interior visualizations and supplies those visualizations to the BIV system for display within a GUI provided by the BIV system, such as along with various user-selectable controls to specify customizations or otherwise modify the GUI, and/or along with various additional types of information to assist the end-user (e.g., displays of actual previous uses of the same or similar customizations in other buildings, suggestions for other customizations based on other previous uses, etc.)—such an RVG system may, in some such embodiments, be part of or otherwise integrated with the BIV system (e.g., operated together on one or more common server computing systems), while in other embodiments the RVG system may operate separate from the BIV system (e.g., be operated by a different entity than the operator of the BIV system, and/or execute on different computer systems and interact with the BIV system's computer system(s) via one or more intervening computer networks, and/or further supply simulated building interior visualizations to other systems than the BIV system, etc.). Additional details are included below regarding simulated building interior visualizations.

As noted above, the BIV system may provide a GUI to an end-user to enable the end-user to customize a building's interior in various manners. In at least some embodiments, the BIV system may receive information to associate a particular end-user with a particular building floor plan, such as to receive such information from a partner entity (e.g., a builder or seller that is providing a particular building to that particular end-user) or from that particular end-user (e.g., via a selection by the end-user from multiple possible floor plans associated with a particular partner entity or that are otherwise available to that end-user, optionally based on criteria specified by or otherwise associated with that end-user), and then use that floor plan and its associated defined constraints for enabling the end-user to customize the interior of a specific instance of the building based on that floor plan. The BIV system may further control the GUI in various manners to enable customizations of that end-user of that floor plan, such as via one or more of the following:
by providing a visual UI wizard or other sequence of selection options to be made by the end-user (e.g., with respect to particular rooms, particular defined surfaces or other internal elements, particular materials or other options to use for the customizations, etc.);
by restricting options for a particular type of end-user customization to those candidate options that are available to the end-user in accordance with any applicable defined constraints;
by displaying additional associated information simultaneously with a displayed visualization of one or more room portions, such as some or all of the floor plan (e.g., with additional icons or other visual information displayed on the floor plan that are associated with the visualized one or more room portions and/or with currently available customization options and/or with previously made customizations), such as displays of actual uses of the same or similar customizations made by the end-user, such as displays of suggestions for other customizations based on the current and/or previously made end-user customizations, etc.;
by displaying or otherwise providing additional information associated with current and/or previously made end-user customizations, such as information for use in ordering and/or purchasing associated construction materials, information for use in delivering such construction materials to the building site, information for use in installing or otherwise performing the construction, etc.;
by enabling an end-user to interact directly with a displayed simulated building interior visualization (whether a visualization of a default version of one or more room portions without any end-user customizations, or a visualization that includes one or more end-user customizations that have already been performed) to provide one or more further end-user customizations for the displayed room portion(s), such as to select a defined surface or a surface subset that includes some of a defined surface in order to specify a further customization for that selected area (e.g., to specify a rectangular subset of a wall or a floor that includes a different material or other end-user customization that the other parts of that wall or floor); etc.

Various types of user-selectable controls may be further provided to enable an end-user to make various customization selections and/or otherwise access and use other types of provided functionality. Additional details are included below regarding example GUIs and associated uses to enable end-user customizations of building interiors.

The described techniques provide various benefits in various embodiments, including to display simulated building interior visualizations via automated operations of one or more computing systems and based on particular user-specified customizations and/or other specified conditions, such as from floor plans for a building and using defined constraints related to the building and the possible customizations. Such described techniques may, in at least some embodiments, be used to provide an improved GUI in which an end-user may more accurately and quickly specify customizations for a building's interior, may produce improved customizations via immediate visual feedback from selected possible customizations, may improve a subsequent process to construct or otherwise implement those customizations, etc. Various other benefits are also provided by the described techniques, some of which are further described elsewhere herein.

For illustrative purposes, some embodiments are described below in which specific types of information are acquired, generated, used and/or presented in specific ways for specific types of structures and by using specific types of devices—however, it will be understood that the described techniques may be used in other manners in other embodiments, and that the invention is thus not limited to the exemplary details provided. As one non-exclusive example, while simulated building interior visualizations may be used for houses in some situations, it will be appreciated that such information may be similarly generated and used in other embodiments for other types of buildings (or other structures or layouts) separate from houses and/or for other parts of a house or other building (e.g., for external walls; surrounding yards; roofs; etc.). As another example, while simulated building interior visualizations based on end-user customizations may be displayed to end-users in some embodiments, such simulated building interior visualizations and/or other associated information may be used in other manners in other embodiments, including to assist in the construction of a building with the customized interior (e.g., information to order and/or purchase associated construction materials, information to deliver the construction materials to the building site, information to install or otherwise perform the construction, etc.). In addition, the term “building” refers herein to any partially or fully enclosed structure, typically but not necessarily encompassing one or more rooms that visually or otherwise divide the interior space of the structure—non-limiting examples of such buildings include houses, apartment buildings or individual apartments therein, condominiums, office buildings, commercial buildings or other wholesale and retail structures (e.g., shopping malls, department stores, warehouses, etc.), etc. Also, various details are provided in the drawings and text for exemplary purposes, but are not intended to limit the scope of the invention. For example, sizes and relative positions of elements in the drawings are not necessarily drawn to scale, with some details omitted and/or provided with greater prominence (e.g., via size and positioning) to enhance legibility and/or clarity. Furthermore, identical reference numbers may be used in the drawings to identify similar elements or acts.

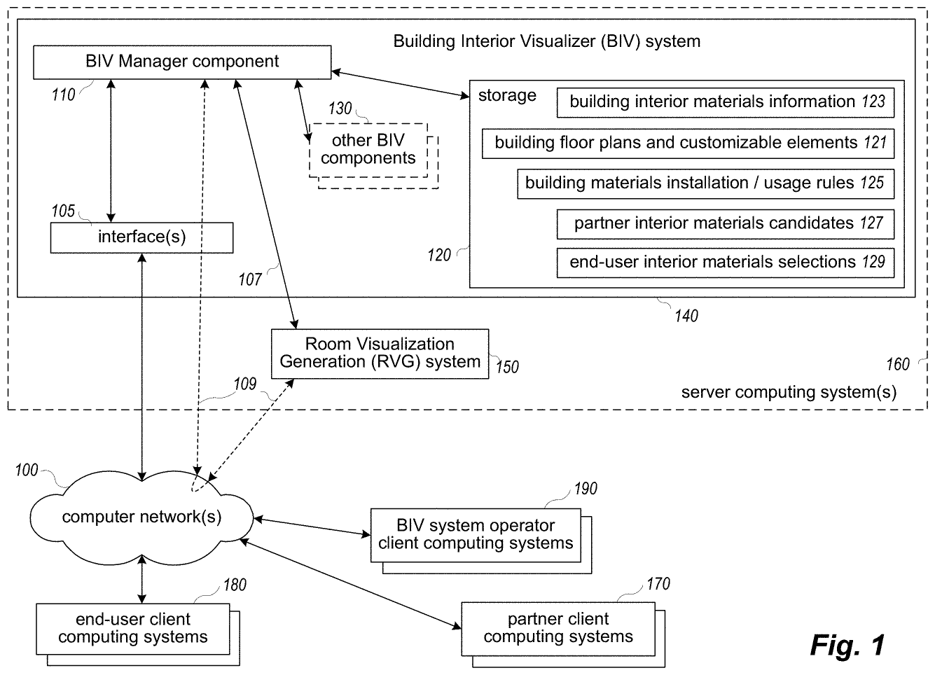

FIG. 1 is a network diagram illustrating an example environment in which a system for performing at least some of the described techniques may operate. In particular, an embodiment of a BIV system 140 is executing on one or more computing systems (not shown), including in the illustrated embodiment to operate in an online manner and provide a GUI (not shown) and/or other interfaces 105 to enable one or more remote users (not shown) of client computing systems 170, 180 and/or 190 to interact over one or more intervening computer networks 100 with the BIV system 140, including to receive defined constraints and other information (e.g., floor plans) for buildings from users representing one or more partner entities and using partner client computing systems 170, to receive defined constraints and/or other information (e.g., specified of defined surface areas and other defined interior elements that are customizable by end-users within particular floor plans) from users representing the operator of the BIV system and using BIV system operator client computing systems 190, and to receive specified customizations for particular floor plans and optionally additional information from end-users using end-user client computing systems 180. The process of the various remote users interacting with the BIV system 140 may involve a variety of interactions over time, as well as independent actions of different groups of users, as discussed in greater detail elsewhere.

In addition, a separate RVG (Room Visualization Generation) system 150 is illustrated in this example embodiment, such as to generate simulated building interior visualizations for particular floor plans and end-user customizations and to supply 107 such generated information to the BIV system, as well as to exchange other information with the BIV system (e.g., related to end-user modifications to or other selections of information in displayed simulated building interior visualizations). In some embodiments, the BIV system 140 and RVG system 150 may operate as part of a single system 160, including in some such cases to execute on the same one or more server computing systems (e.g., if such systems are operated by a single entity or are otherwise executed in coordination with each other)—if so, the supply interactions 107 may occur directly between the systems 140 and 150 without passing through the network(s) 100. In other embodiments, the BIV system may instead operate separately from such an RVG system, including in at least some such cases to execute on different server computing systems—if so, the supply interactions 107 may actually occur via interactions 109 over the computer network(s) 100.

In the illustrated embodiment, the BIV system 140 includes various components that interact with each other to provide the described techniques, including a Manager component 110, one or more interfaces 105, and optionally other BIV components 130 to provide additional types of functionality and/or information. In this example, the BIV system 140 further includes various information 121-129 on storage 120 (e.g., in one or more databases, not shown), such as building floor plans and customizable elements information 121 (e.g., received from partner client computing systems 170 and/or BIV system operator client computing systems 190), building interior materials information 123 (e.g., received from partner client computing systems 170 and/or BIV system operator client computing systems 190), building materials installation and usage rules 125 (e.g., received from partner client computing systems 170 and/or BIV system operator client computing systems 190), partner-specified candidates for and constraints related to building interior materials and other customizations 127 (e.g., received from partner client computing systems 170), and end-user supplied information 129 (e.g., received from end-user client computing systems 180) that includes customization selections for particular building floor plans and optionally additional associated information (e.g., contact information and other related information for an account of an end-user with the BIV system, information about end-user interactions with a displayed simulated building interior visualization, etc.). The Manager component 110 manages the operations of the BIV system using the information in the storage 120, such as the interactions with the client computing systems 170-190 and the RVG system 150 via the interfaces 105, including performing interactions with the end-user client computing systems 180 to provide the GUI and to receive end-user interactions that specify end-user customizations for particular building floor plans and that otherwise access functionality provided by the BIV system. Additional details are included elsewhere herein regarding the operations of the BIV system.

The network 100 may, for example, be a publicly accessible network of linked networks, possibly operated by various distinct parties, such as the Internet, with the BIV system 140 available to any users or only certain users over the network 100. In other embodiments, the network 100 may be a private network, such as, for example, a corporate or university network that is wholly or partially inaccessible to non-privileged users. In still other embodiments, the network 100 may include one or more private networks with access to and/or from the Internet. Thus, while the BIV system 140 in the illustrated embodiment is implemented in an online manner to support various users over the one or more computer networks 100, in other embodiments a copy of the BIV system 140 may instead be implemented in other manners, such as to support a single user or a group of related users (e.g., a company or other organization), such as if the one or more computer networks 100 are instead an internal computer network of the company or other organization, and with such a copy of the BIV system optionally not being available to other users external to the company or other organizations. The online version of the BIV system 140 may in some embodiments and situations operate in a fee-based manner, such that the one or more users provide various fees to use various functionality of the BIV system, such as to perform interactions related to presenting simulated visualizations of building interior information in a user-customized manner. In addition, the BIV system 140 and each of its components, as well as the RVG system if separate from the BIV system, may include software instructions that execute on one or more computing systems (not shown) by one or more processors (not shown), such as to configure those processors and computing systems to operate as specialized machines with respect to performing their programmed functionality.

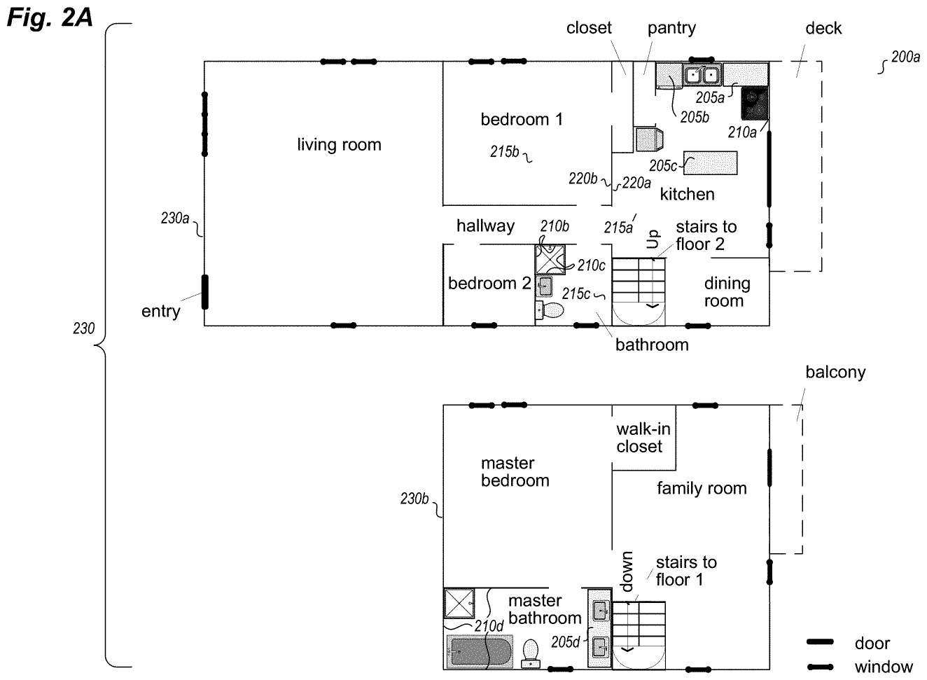

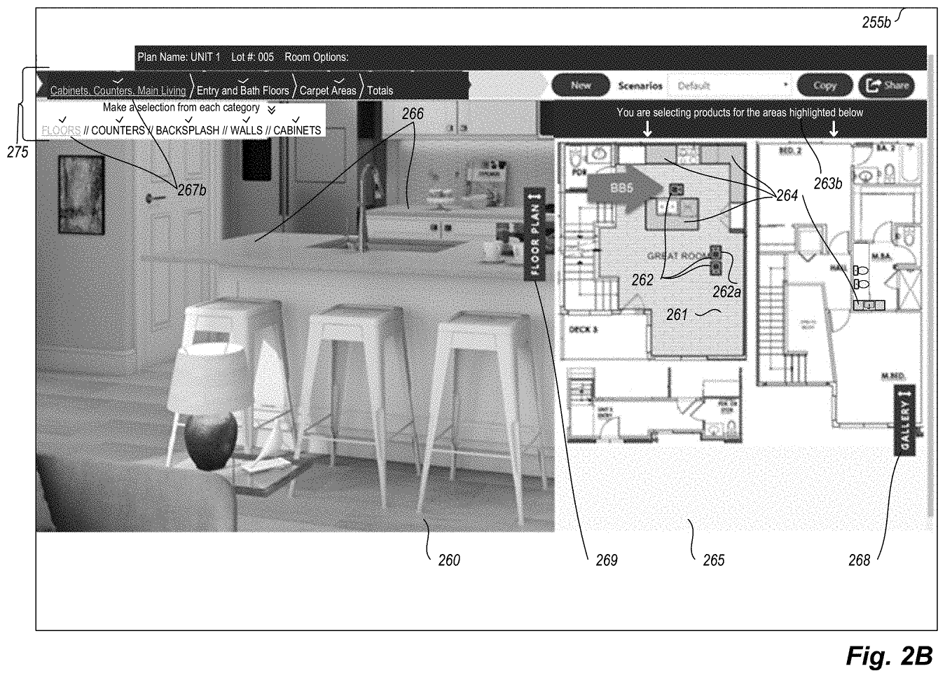

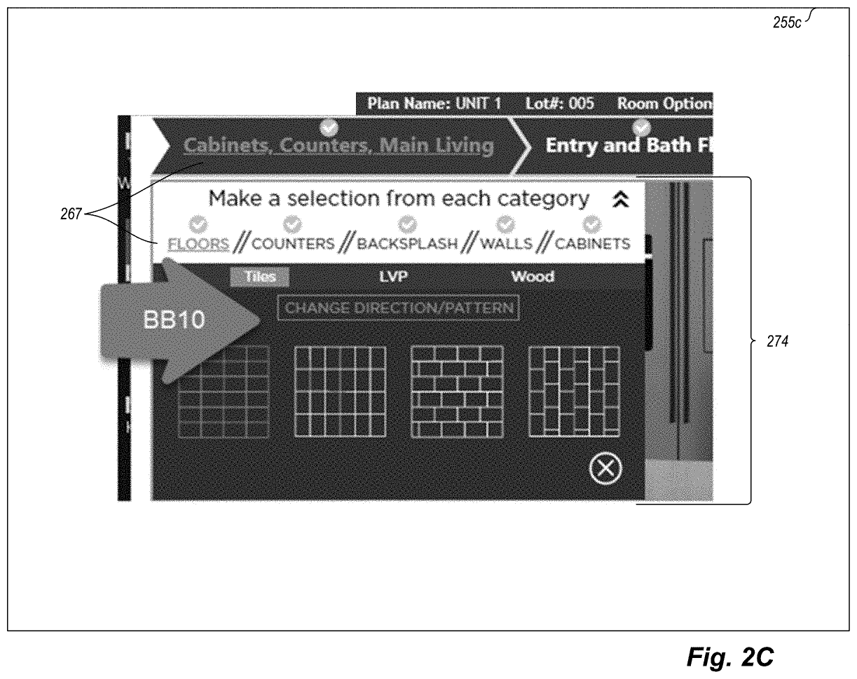

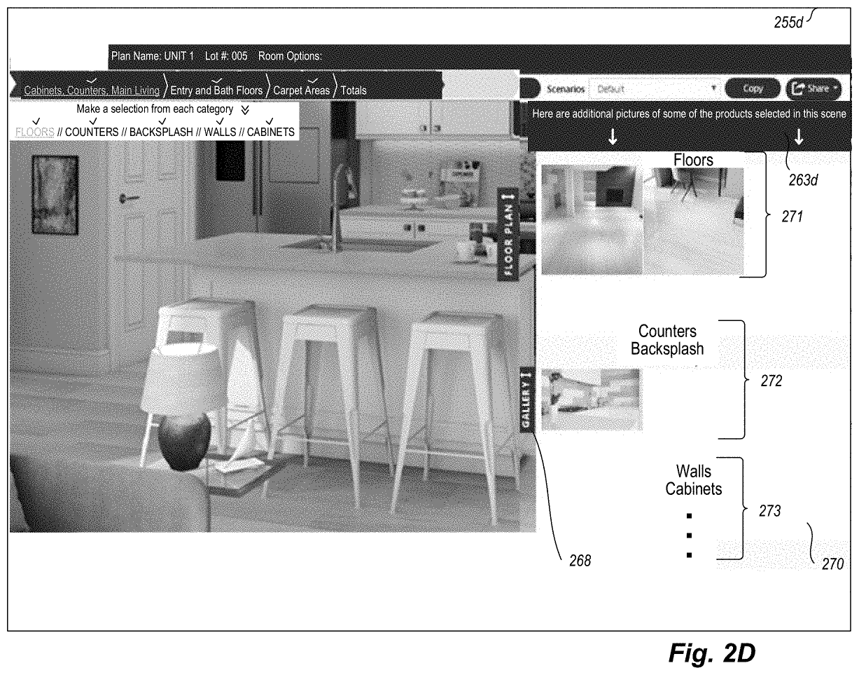

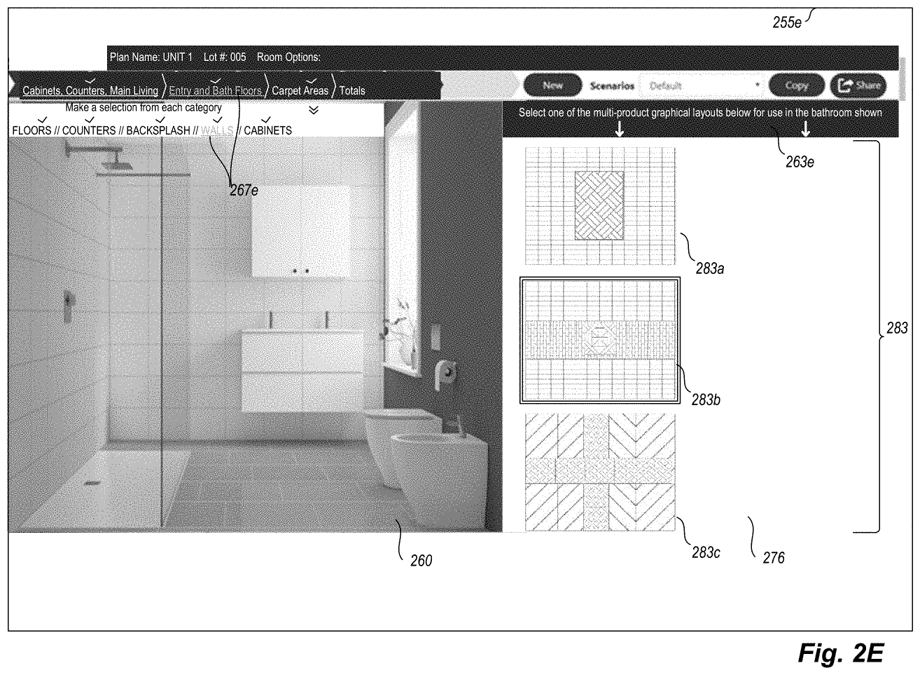

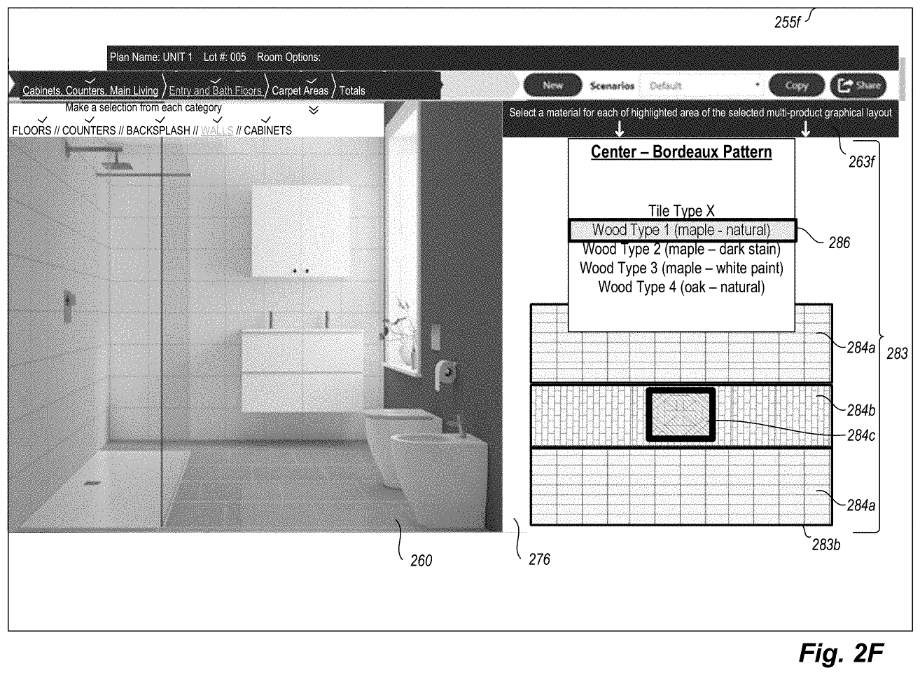

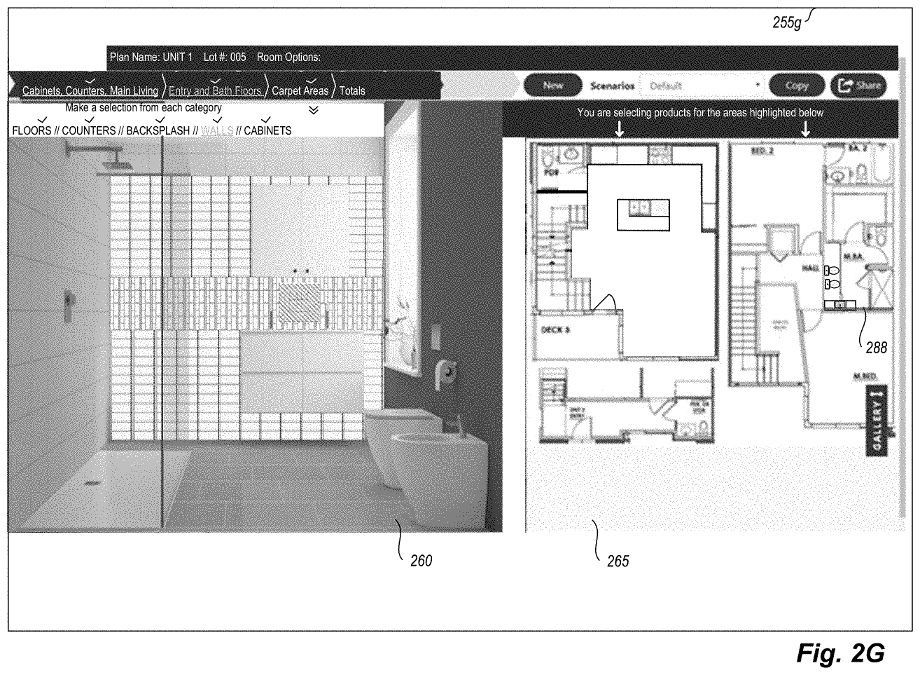

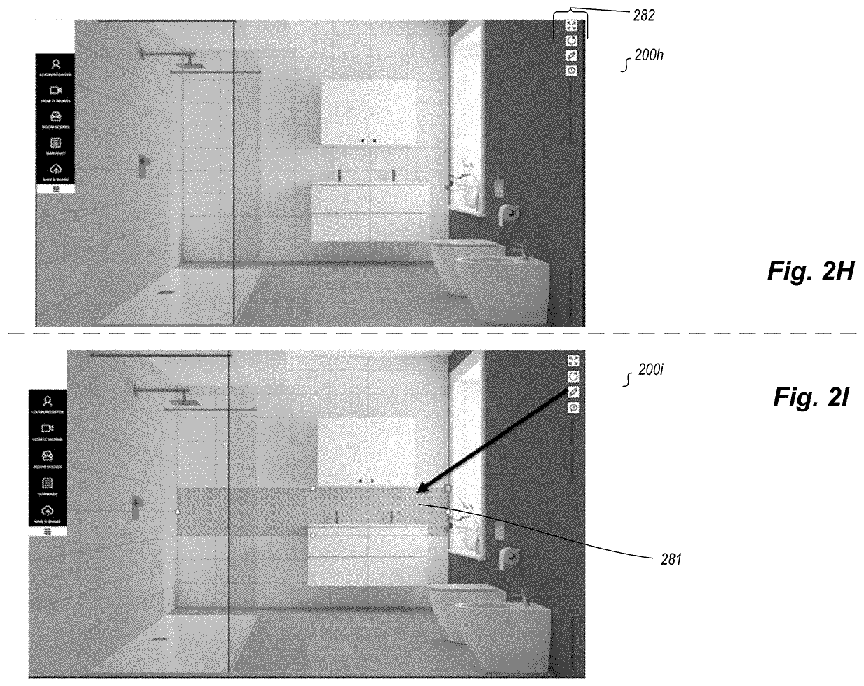

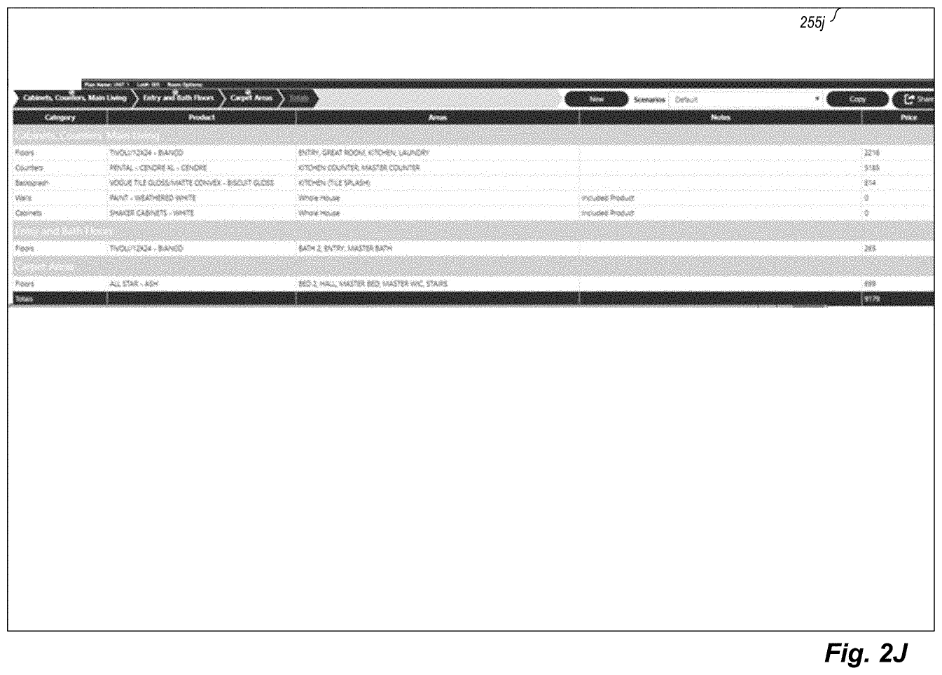

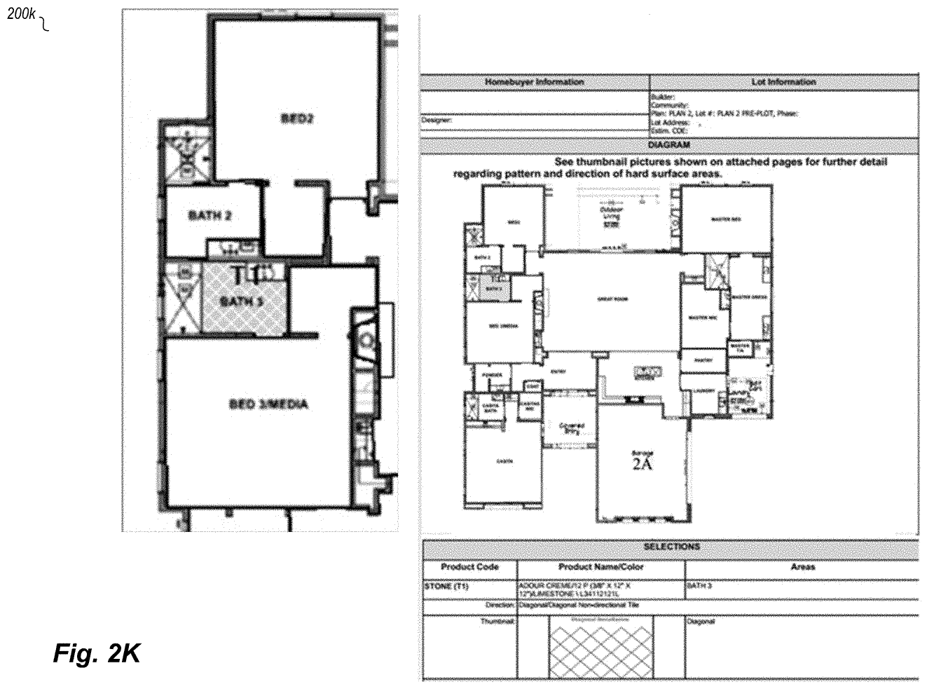

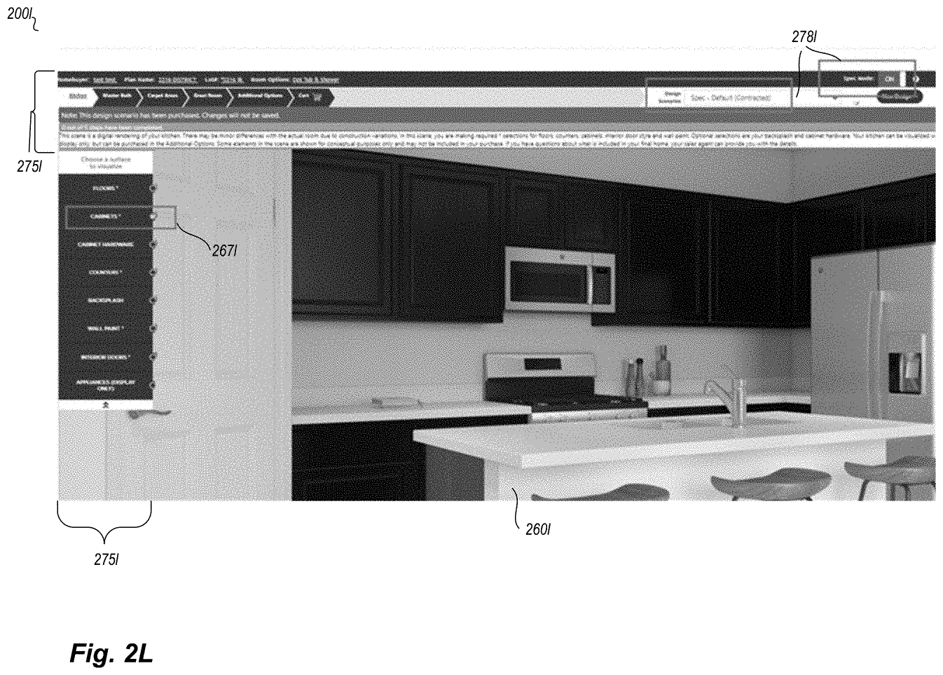

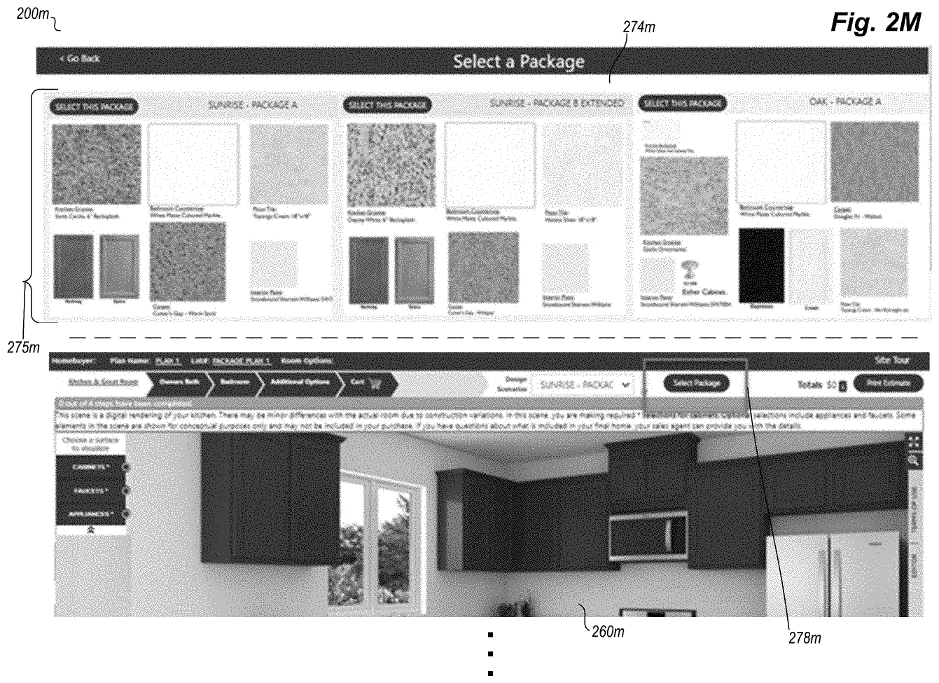

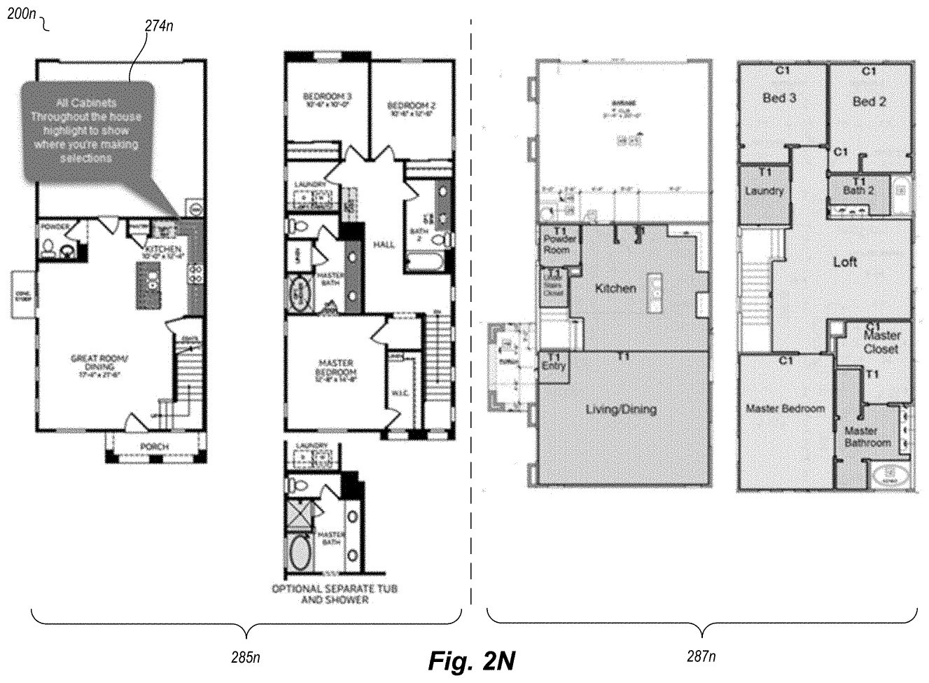

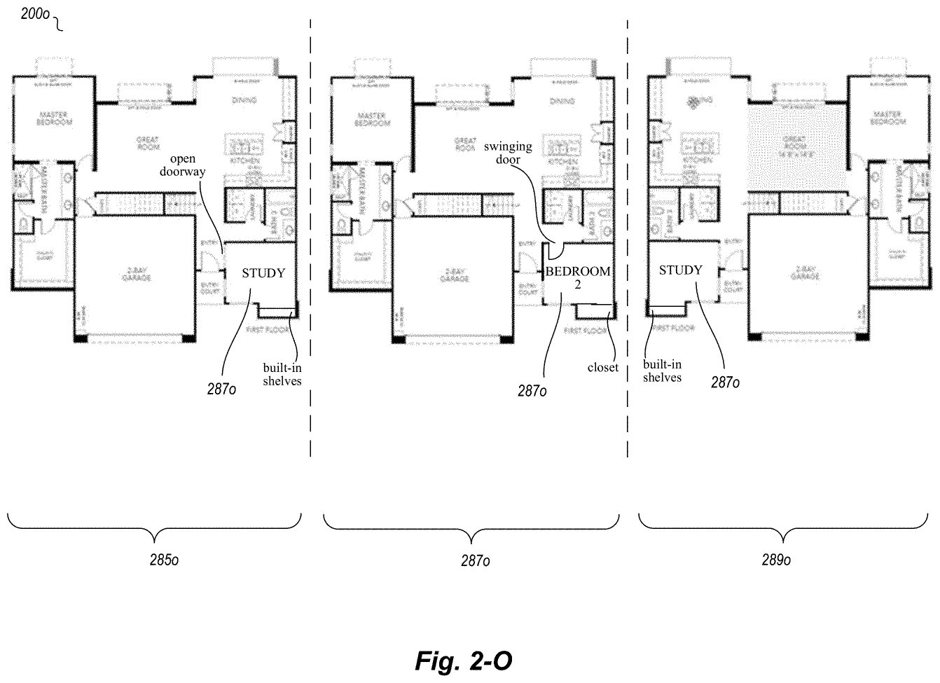

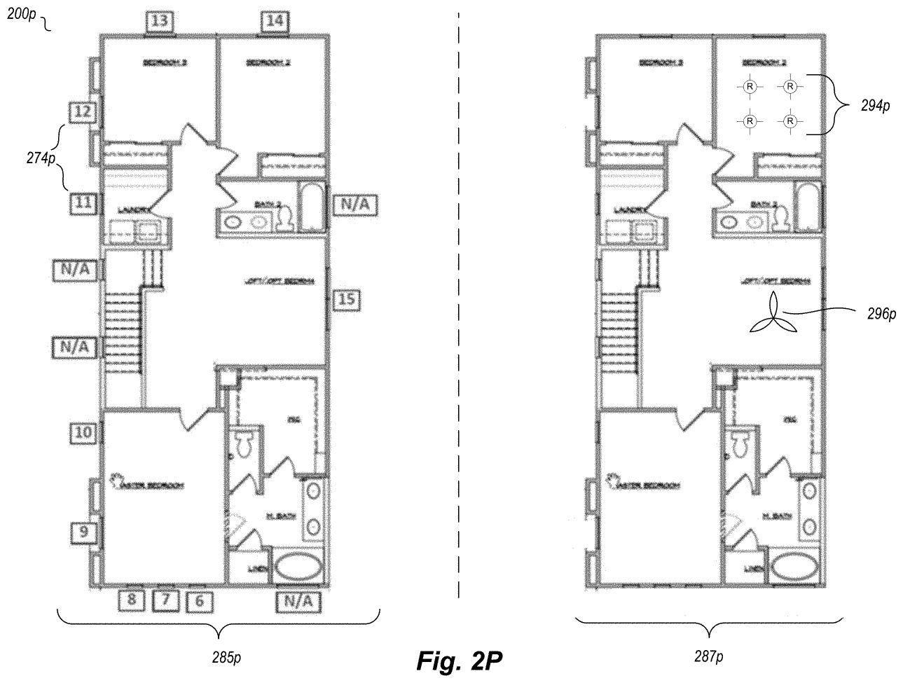

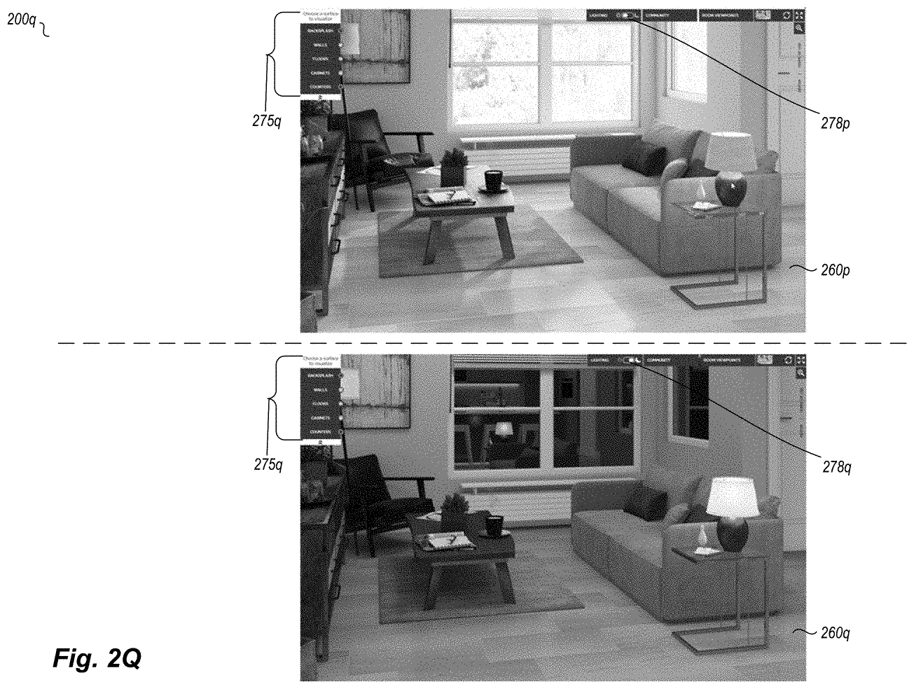

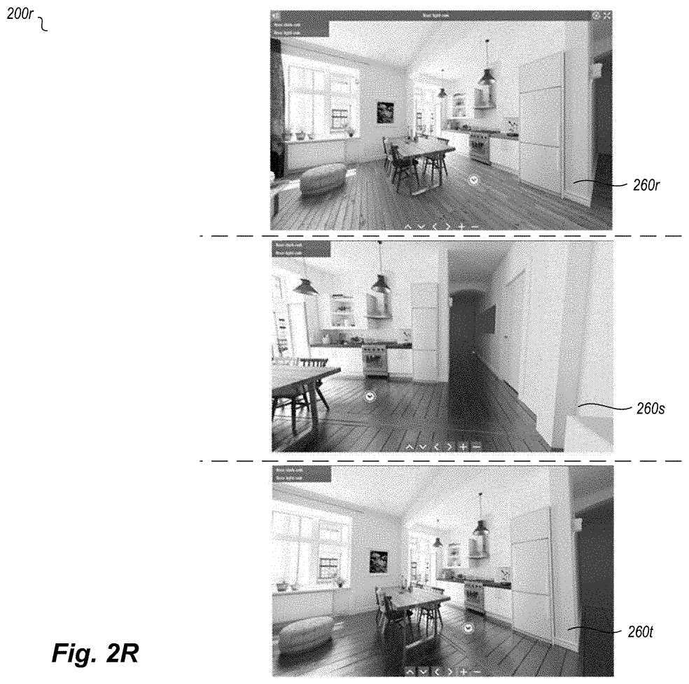

FIGS. 2A-2R illustrate examples of techniques for presenting simulated visualizations of building interior information in a user-customized manner and based on employing defined constraints (including examples of using a GUI to enable end-user visualization of a customized house interior), and for generating and providing additional associated information.

In particular, FIG. 2A illustrates information 200a that includes an example floor plan 230 of a house, which in this example is a two-story house with corresponding sub-plans 230a and 230b for the two stories. In this example, room labels are shown for some or all rooms (e.g., “living room”, as shown for the living room), and visual indications of fixtures or appliances or other built-in features may be included for some or all rooms (e.g., as shown for the kitchen and bathrooms). In this example, the example floor plan illustrates information about doors and windows in the house, as well as an exterior deck and balcony, and interior elements that include a kitchen island 205C—it will be appreciated that a variety of other types of information may be included for a floor plan in at least some embodiments and situations, such as dimensions information, labels for particular displayed elements other than room types, other types of interior elements beyond fixtures and appliances, etc. To prepare such a floor plan for use in subsequent customizations by one or more end-users to customize one or more corresponding buildings based on the floor plan, the described techniques may include receiving and storing information about defined interior surfaces and other interior elements that are customizable by end-users, such as horizontal surfaces 205 (including kitchen counter surfaces 205a and 205b, kitchen island surface 205c and bathroom counter surface 205d), floors 215 (with example floors including the kitchen floor 215a, a bedroom floor 215b, and a bathroom floor 215c), walls 220 (with example walls including a wall 220a in the kitchen and a wall 220b in bedroom 1), other specialized elements 210 (including a backsplash 210a behind a stove, shower walls 210b, free-standing shower enclosure walls 210c, and bathroom walls 210d surrounding a shower and/or bath), etc.—it will be appreciated that a variety of other types of defined surfaces or other defined interior elements may be specified in other embodiments. It will also be appreciated that a variety of other types of information may be added in some embodiments, that some of the illustrated types of information may not be provided in some embodiments, and that visual indications of various types of information may be displayed and selected in other manners in other embodiments.

FIG. 2B continues the example of FIG. 2A, and illustrates an example GUI screen 255b, which in this example includes a pane or other area 265 that shows a building floor plan, a pane or other area 260 that shows a simulated building interior visualization corresponding to the displayed floor plan (in particular, a simulated building interior visualization of a portion of a kitchen/great room area of the floor plan that is highlighted), additional area 275 to provide user-selectable controls and associated information, and other user-selectable controls at other areas (such as controls 268 and 269). The example floor plan illustrated in FIG. 2B is a different floor plan from that shown in FIG. 2A, although in other examples the same floor plan could instead be displayed in FIG. 2B. In this example, the area 275 displays information about a UI wizard or other series of steps for an end-user to perform to specify customizations of a building based on the illustrated floor plan, with current selections 267b corresponding to customizing floors, cabinets and counters in a main living area of the floor plan that includes the kitchen/great room. Current customizable elements include countertop surfaces 266 in the simulated building interior visualization, with corresponding information 264 shown in the displayed floor plan. The customizable floor 261 of the kitchen/great room is further illustrated in the floor plan, along with information 263b to provide instructions regarding the customizations to currently perform to an end-user interacting with the GUI. In this example, the floor plan further includes icons 262 to illustrate locations within the kitchen/great room from which a corresponding simulated building interior visualization may be generated, with the icon 262a corresponding to a current visualization, and with the icons being user-selectable controls in at least some embodiments that an end-user can select to change the currently displayed simulated visualization (such as to select the illustrated BB5 icon to change the current visualization).

The end-user can specify customizations to be made in various manners in various embodiments, such as to select a defined interior surface or other defined interior element from the floor plan and/or from the current visualization, and then specify a customization for that selected surface/element (e.g., from a list or other group of candidate options for that customization). As discussed in greater detail elsewhere, the candidate options for a customization may be selected and/or presented in accordance with defined constraints, such as to use a defined group of candidate options, which in at least some cases may be restrained based on previous customizations. In addition, the floor plan may be updated to reflect end-user customizations that are made, such as to use color or other visual indications to indicate multiple areas that have received the same customization—in this example, the illustrated surfaces 264 have been specified by a defined constraint to use the same customization, such that a selection of tile or other material for one of the surfaces will cause a corresponding selection for the other surfaces 264. In a similar manner, the floor 261 of the kitchen/great room may be associated with one or more other areas of the floor plan, although such other areas are not illustrated in this example. Once an end-user customization has been specified, the displayed simulated visualization may be updated to show that customization, such as to allow an end-user to see the effects of customization selections in a photo-realistic simulated visualization (e.g., in real-time), and to thus allow the end-user to determine a preferred customization from among multiple candidate options. It will be further appreciated that the photorealistic simulated visualization in this example involves including additional non-custom izable interior elements in the visualization, such as chairs, a table, a lamp, a couch, a picture, items on counters, etc., although in other embodiments such additional elements may not be shown.

FIG. 2C continues the examples of FIGS. 2A-2B, and illustrates a portion 255c of a GUI screen to provide further details about an example for performing end-user customization of a selected floor. In this example, the displayed information includes part of the GUI wizard or other sequence of end-user operations from area 275, which prompts 267 an end-user to specify a material and associated information for the floor using displayed information 274, which in this example includes a selection to use tiles (from the candidate options of tiles, wood, and luxury vinyl plank, or LVP), and further illustrates options of patterns and directions of tiles that can be selected for the customization. While not illustrated in this example, the end-user may further proceed to select a particular tile as part of the customization, whether before or after the selection of the direction/pattern. After the customization for the selected floor is performed, the end-user may be further prompted to customize a next type of option via the interface 275, which in this example includes counters, then one or more backsplashes, then walls, and then cabinets. After cabinets, counters and floors are specified for the main living area, the end-user may be further prompted to specify various information for entry and bath floors, followed by other types of customizations to be specified. In this example, the displayed portion of the GUI further illustrates that the floor plan in use is given a label of “unit 1”, and the customized version of this floor plan is intended to be built in an area refer to as lot number 005. It will be appreciated that various other types of information may be displayed in such a user interface.

FIG. 2D continues the examples of FIGS. 2A-2C, and illustrates a GUI screen 255d that includes a simulated room visualization in a manner similar to that of FIG. 2B, but in which the end-user has selected control 268 to display a pane or other area 270 that includes a gallery of images in place of the floor plan pane/area 265 of FIG. 2B (although in other embodiments the gallery could instead be displayed simultaneously with the simulated room visualization and the floor plan). In this example, the gallery includes instructions 263d for the end-user regarding the displayed information in the gallery pane/area, which includes pictures of actual prior installations corresponding to one or more customizations made by the end-user, such as images 271 of corresponding installed floors, images 272 of corresponding installed counters and backslashes, information 273 about corresponding installed walls and cabinets, etc. While not illustrated in this example, the gallery or another similar pane/area could further display images or other information about further suggested customizations that the end-user could make based on end-user customizations that have already been made, such as suggested customizations determined from other actual combinations of customizations previously made by other end-users.

FIG. 2E continues the examples of FIGS. 2A-2D, and illustrates a GUI screen 255e that includes a simulated room visualization in pane/area 260 in a manner similar to that of FIG. 2B, but with the simulated room visualization of FIG. 2E being for a different room in the floor plan, and in particular for a master bathroom, as part of continuing customizations by the end-user for a building based on the floor plan illustrated in FIG. 2B (and as reflected by current highlighted portions 267e of the GUI wizard or other sequence 275 of customization activities). In this example, the simulated room visualization reflects default tile selections that have been made for the floor and walls around a shower and sink, as well as information for other parts of the bathroom, before any end-user customizations have been made. FIG. 2E further includes a pane or other area 276 that includes various alternative multi-product graphical layouts 283, to reflect that the end-user has selected to customize a wall in the master bathroom using one of the multi-product graphical layouts, and with the instructions 263e indicating to select one of the graphical layouts to use in further proceeding. In this example, the end-user has selected multi-product graphical layout 283b, which includes three defined areas of the wall with specified positioning relative to each other and with different patterns for three different materials to be included in those three defined areas—in the example of FIG. 2E, the end-user will proceed to specify the materials to use for each of the three defined areas, as discussed further with respect to FIG. 2F, but in other embodiments and situations one or more of the three different materials for the selected graphical layout may instead be predefined and included as part of the selected graphical layout.

FIG. 2F continues the examples of FIGS. 2A-2E, and illustrates a GUI screen 255f that corresponds to continuing activities of the end-user in using the selected graphical layout 283b to customize a wall in the master bathroom. In particular, pane/area 276 has been updated to show the graphical layout being customized with particular materials by the end-user, with the end-user currently using the list 286 (e.g., a dropdown list) to select a specific type of wood to include in area 284c of the graphical layout 283b, as reflected by the displayed instructions 263f, and with the other two areas 284a and 284b having previously been specified by the end-user (e.g., in a similar manner) to use two different types of tiles, and with the pattern for each of the three areas being used from the selected graphical layout.

FIG. 2G continues the examples of FIGS. 2A-2F, and illustrates a GUI screen 255g that corresponds to the continuing activities of the end-user in customizing a building based on the floor plan illustrated in FIG. 2B, and with an updated version of the floor plan illustrated in pane/area 265 of FIG. 2G using the selected graphical layout 283b to customize a wall in the master bathroom. In particular, the floor plan includes a new highlighted area 288 to show the wall of the master bathroom being customized, and with pane/area 260 including an updated version of the simulated bathroom visualization previously shown in FIGS. 2E and 2F, with the updated version showing the end-user customizations based on the selected graphical layout.

FIGS. 2H and 2I continue the examples of FIGS. 2A-2G, and illustrate information 200h and 200i, respectively, that show alternative options for customizing the master bathroom using the simulated visualization of the bathroom area shown in FIGS. 2E-2F. In this example, user-selectable controls 282 are included that allow the end-user to select particular areas of interest to customize, such as using paint-type GUI tools to specify a geographical shape (e.g., a rectangle, oval, etc.) and/or a free-form shape. FIG. 2I further illustrates how the end-user may interact with the displayed simulated visualization to specify an area 281 to be further customized, which in this example is a rectangular subset of the larger wall area that has a different type of tile or other material than the rest of the wall (referred to at times as an ‘insert’ or ‘cutout’), but in other embodiments and situations may be any free-form shape drawn by the end-user (e.g., using the paint-type GUI tools). While not illustrated in FIGS. 2H and 2I, the end-user may be further prompted to specify a type of material and associated information (e.g., a pattern) to be used for the selected subset being further customized. It will be appreciated that a variety of other types of area subsets/insert customizations may be performed in other situations, including with respect to floors, ceilings, horizontal surfaces, etc.

FIG. 2J continues the examples of FIGS. 2A-2I, and in this example illustrates a GUI screen 255j that shows a table with further information for display to the end-user related to customizations that have been selected so far. In this example, the displayed information illustrates selections made for multiple sections of the GUI wizard, such as for cabinets, counters and the main living area, for entry and bath floors, for carpet areas, etc., and with corresponding total information available to be displayed (e.g., a total cost or some other total aggregate information about the selected end-user customizations). It will be appreciated that similar information may be displayed in other manners in other embodiments, including by overlaying the information on a floor plan view and/or on a simulated visualization view, and/or the displayed information or similar information may be provided in other manners in other embodiments (e.g., via printed reports, via electronic communications, etc.).

FIG. 2K continues the examples of FIGS. 2A-2J, and illustrates an example of an additional type of information that may be generated and provided by the BIV system to correspond to customizations performed by an end-user. In particular, FIG. 2K illustrates information 200k that provides a color diagram corresponding to end-user customizations to be made, with color used to illustrate types of customizations to be performed, and with a portion of the floor plan broken out in a separate blown-up illustration to the left of the color diagram. Information 200k further illustrates an example of installation instructions that may be automatically generated and provided by the BIV system for end-user customizations, with the example in FIG. 2K including a visual illustration of a tile pattern to be installed, along with information about the specific tile to use—it will be appreciated that installation instructions may be generated in other formats (e.g., included in electronic messages) and with other types of information in other embodiments and situations. While not illustrated in FIG. 2K, the BIV system may generate and provide various other types of additional information in other embodiments and situations, such as one or more of the following: a list of installation activities (e.g., a material and labor item list) to be performed corresponding to the end-user customizations (e.g., to correspond to a stone product installed in an upstairs bathroom on a diagonal direction), along with associated information such as quantities, colors, size, cost, etc.; a list of rooms along with associated information such as room type, subflooring type, square feet, etc.; information for use in further interactions between the end-user and a corresponding partner entity (e.g., a builder or seller), such as a detailed sales estimate, a sales contract, care and maintenance information, purchase contract terms, a purchase order, a work ticket, etc. a list of types of materials corresponding to the end-user customizations along with associated information for those materials (e.g., information about installation time and/or costs associated with use of the materials); etc.—some or all of the additional information may, for example, reflect defined constraints that include business rules using a varied number of factors. Thus, in at least some embodiments, the BIV system may provide functionality to dynamically create sales orders as end-users are making customization selections that include pricing and/or other details corresponding to those customization selections. It will be appreciated that in some embodiments the partner entity and the operator of the BIV system may be the same entity, such that some or all of the additional types of information is instead for further interactions between the end-user and the operator of the BIV system. It will also be appreciated that a variety of other types of information related to the end-user customizations may be generated and provided, such as installation instructions, materials ordering or restocking information or instructions, materials delivery information or instructions, etc.

FIG. 2L continues the examples of FIGS. 2A-2K, and illustrates information 200I that includes an example GUI screen, which in this example includes a pane or other area 260I that shows a simulated building interior visualization of a portion of a kitchen area, and additional areas 275I to provide user-selectable controls and associated information, including user-selectable controls 267I and 278I in this example. The example kitchen area illustrated in FIG. 2L is different from that shown in FIG. 2B, although in other examples the same kitchen area could instead be displayed in FIG. 2L. In this example, the controls 275I allow a representative of a partner entity associated with a building (e.g., a builder who constructs the building, an owner or other entity who sells the building, a remodeler who remodels or otherwise modifies an existing building, an organization to which an end-user belongs, etc.) to specify information to be later used as constraints or other limits on customizable candidate options that end-users can later select and use for customizations. For example, a new-house production builder partner entity may, for some or all new houses being built, make preselections of items to be included/excluded and/or of materials to be used/unused for parts of those houses, before end-users may further make other customizations to those houses for things other than those preselections—such preselection specifications may, in some embodiments and situations, be referred to as being part of a “spec mode”. In the example of FIG. 2L, the partner entity representative is, in accordance with controls 267I and 278I, preselecting cabinetry to be included in the kitchen as part of such a spec mode, with that preselected cabinetry to later be treated as a constraint that an end-user may not change for the one or more houses to which the preselections apply (even if other houses using the same floor plan do not have such preselections for those other houses), although it will be appreciated that a variety of other items and/or materials may be preselected in other embodiments and situations. When the end-user later receives a simulated building interior visualization of a portion of this kitchen area for one of the houses specified by the partner entity to use such preselections, such as part of customization activities by that end-user, the preselected items (e.g., here, a particular style, material and color of cabinetry) may be included in that visualization and not be further customizable or modifiable by that end-user.

FIG. 2M continues the examples of FIGS. 2A-2L, and illustrates information 200m that includes an example GUI screen, which in this example includes a pane or other area 260m to enable an end-user to customize a house by selecting one of multiple predefined groups or ‘packages’ 275m that each has multiple preselected materials and/or items that an end-user may select as part of customizing a particular house (e.g., for use together within a particular room), with examples of such user-selectable groups/packages shown in this example in a separate breakout area 274m (e.g., in a pop-up window or other display after user-selectable control 278m is selected). In this example, a partner entity associated with a building has previously specified information to be later used as constraints or other limits on customizable candidate options that end-users can later select and customize, and in particular has specified multiple such defined alternative groups/packages—such preselection specifications may, in some embodiments and situations, be referred to as being part of a “builder package”. In the example of FIG. 2M, the partner entity has specified each predefined group/package to include one or more types of cabinets and accompanying materials and/or colors for the cabinets and/or surrounding areas (e.g., countertop above or below the cabinets), to later be treated as constraints such that an end-user may not change selected items within a particular selected group/package but can make customizations by selecting which of the multiple alternative groups/packages to use, and in some cases to customize additional items or materials to use together with a selected group/package (not shown here), although it will be appreciated that a variety of other items and/or materials may be preselected for such groups/packages in other embodiments and situations (e.g., grout color; installation method, such as staggered or straight; etc.) and that some or all such groups/packages may have an associated price in at least some such embodiments. When an end-user is customizing such a house using an interface such as that shown in pane 260m and area 274m, the predefined groups/packages may be made available to the end-user for selection, such as in a manner similar to that of area 274m of FIG. 2M, and corresponding simulated visualizations may be later provided that use information specified in one or more such selected groups/packages.

FIG. 2N continues the examples of FIGS. 2A-2M, and illustrates information 200n that includes examples of information that may be displayed in one or more GUI screens, such as to an end-user who is performing customizations of a particular house or to a representative of a partner entity who is specifying packages or other preselections, candidate options and/or other constraints. In this example, the information includes a floor plan 285n that interactively provides information to an end-user or a partner entity representative to illustrate areas of the floor plan that are available for customization or other specification (e.g., specification of associated preselections, packages, candidate options and/or other constraints) and/or that are currently or recently customized or otherwise specified, such as to update the floor plan with visual information to show customizations that have been made, and with such functionality provided via such a floor plan being referred to in some embodiments and situations as being part of an “interactive floor plan”. In at least some such embodiments, customizable and/or customized areas of such a floor plan may further be user-selectable, such as to enable an end-user or partner entity representative to select, on the displayed floor plan, an area to be customized, and to then receive further customization option information and selections. In this example, the floor plan 285n includes two sub-floor plans corresponding to two stories of (if an end-user) a specific house to be customized or (if a partner entity representative) a house type or a specific house for which constraint information is to be specified, including displayed information 274n in this example to note that cabinets are currently being customized (if an end-user) or specified for preselections, packages, candidate options and/or other constraints (if a partner entity representative) and that the areas of the house with such cabinets are highlighted (e.g., are shown in red in this example). During such customization and/or specification of preselections/packages/candidate options/constraints, additional information (not shown) may be displayed to enable the customizations or other specifications to be made, such as in a manner illustrated and described elsewhere herein. FIG. 2N further illustrates an additional floor plan 287n that differs from floor plan 285n, with areas of the additional floor plan 287n being highlighted in a manner different than that of floor plan 285n (e.g., by using different colors and corresponding to entire rooms rather than individual areas or items within rooms), such as to correspond to different types of information being customized or otherwise specified (e.g., to specify flooring materials in floor plan 287n), to different times (e.g., with floor plan 287n illustrating the results after selections have been made using highlighting similar to that of floor plan 285n), as two non-exclusive examples of showing different types of highlighting that may be used for areas of a floor plan that are available for customization or other specification and/or that are currently or recently customized or otherwise specified, etc. In at least some embodiments, as an end-user or partner entity representative chooses products or otherwise makes customizations or specifies information for later constraints, a displayed floor plan will use highlighting and/or other visual techniques to indicate where on the floor plan that the selections are being made, and at least some types of customizations or other specified information will be immediately displayed on the floor plan in the areas being customized or specified (e.g., for flooring material, such as to show colors, patterns, directions of installation, etc.). While not illustrated in these examples, in other embodiments additional types of functionality may be provided via such an interactive floor plan interface, such as to enable a user to rotate or flip the floor plan view, to add annotations (e.g., notes, labels, icons, etc.) in specified locations (whether for personalized purposes, such as by an end-user and to only be available to that user; or for more general purposes, such as by a partner entity representative and to be available to anyone viewing that floor plan, including one or more end-users who are later using it for customization purposes), etc.

FIG. 2O (shown as “2-O” in the figures and in some parts of this description to differentiate it from the number “20”) continues the examples of FIGS. 2A-2N, and illustrates information 200o that includes additional examples of information that may be displayed in one or more GUI screens as part of customizations by an end-user and/or as part of specifications by a partner entity representative of preselections, packages, candidate options or other constraints. In this example, the information includes three alternative floor plans 285o, 287o and 289o to provide non-exclusive examples of types of end-user customizations and/or partner entity representative specifications that go beyond visual aspects and include structural modifications to the floor plans and the resulting houses that are built. In this example, floor plans 285o and 287o illustrate alternatives in which the room 298o may be selected to be a study or a bedroom, including in this example to have different doorway placements and types, and to have different built-in structures (e.g., to have a closet in the bedroom in floor plan 287o, and to have built-in shelving in the study in floor plan 285o). It will be appreciated that in at least some embodiments, two or more such alternative structural options may be first defined by a partner entity representative, with one of the alternative options later selected by an end-user as part of the end-user customizations. Floor plan 289o illustrates another type of structural alternative to that of the floor plan 285o that may be first defined by a partner entity representative in some embodiments and situations, with one of the alternatives later selected by an end-user as part of the end-user customizations—in particular, floor plan 289o illustrates a reversed floor plan in which the right and left halves of the floor plan 289o are flipped relative to those of floor plan 285o (e.g., with the study 287o of floor plan 289o now being in the front left of the house as seen from the street, rather than in the front right of the house as seen from the street for floor plan 285o). It will be appreciated that various other types of structural options may be defined and selected in other embodiments.

FIG. 2P continues the examples of FIGS. 2A through 2-O, and illustrates information 200p that includes examples of information that may be displayed in one or more GUI screens, such as to an end-user who is performing customizations of a particular house or to a partner entity representative who is specifying preselections, packages, candidate options or other constraints. In this example, the information includes a floor plan 285p that illustrates various numbered locations 274p at which the end-user or partner entity representative may select and designate window coverings to be used, such as by using selections from a menu or list (not shown) that are dragged to particular numbered locations 274p and dropped on those locations to designate the use of those selections, or that are otherwise designated after one or more such particular numbered locations are selected. While not illustrated in this example, the floor plan and/or a simulated visualization generated using its information may be updated to show the selected window coverings at the specified locations. Floor plan 287p of FIG. 2P continues the example, and illustrates an alternative scenario of specifying types of lighting (with associated electrical wiring and/or connections to be installed) to use at designated locations, such as to use a configuration of 4 ceiling hole ‘can’ lights 294p in Bedroom 3 and to use a fan and chandelier light 296p in a loft area—while not shown for floor plan 287p, the locations that may be customized and/or specified may be designated in various ways, such as using controls similar to those shown for floor plan 285p, or more generally by using interactive floor plan functionality as discussed elsewhere herein. It will be appreciated that various other types of options (including other types of lighting and/or electrical options, various types of window options, other types of window covering options, etc.) may be defined and selected in other manners in other embodiments.

FIG. 2Q continues the examples of FIGS. 2A-2P, and illustrates information 200q that includes an example GUI screen, which in this example includes a pane or other area 260p that shows a simulated building interior visualization of a house interior, and additional areas 275q to provide user-selectable controls and associated information, including user-selectable controls 278p in this example that allow a user to specify a type of simulated lighting to be shown in the simulated interior visualization. In particular, the simulated visualization in area 260p illustrates an example of simulated daylight lighting, such as to show simulated light coming in the illustrated windows. FIG. 2Q further illustrates an additional pane or other area 260q that shows the same simulated building interior visualization of a house interior (e.g., an alternative visualization shown after a user change is made via user-selectable control 278q), but with simulated nighttime lighting, such as show less or no simulated light coming in the illustrated windows but to include simulated light coming from the lamps and other lighting (not shown) in the house interior. It will be appreciated that other types of lighting types may be selected in other manners in other embodiments, with resulting simulated visualizations (not shown) reflecting those other types of lighting.

FIG. 2R continues the examples of FIGS. 2A-2Q, and illustrates information 200r that includes example GUI screens, which in this example includes panes or other areas 260r, 260s and 260t, such as with simulated visualizations to be shown successively in the same GUI pane according to user manipulations via the GUI. In particular, the panes 260r-260t in this example show different views of a simulated building interior visualization of a house interior that is in the form of a panorama image (e.g., a 360° panorama image, such as that includes 360° of horizontal visual coverage around a vertical axis and that optionally further includes 360° of vertical visual coverage around a horizontal axis), and correspond to different viewpoints within that simulated visualization panorama image. For example, an end-user or partner entity representative may manipulate a displayed view of the simulated visualization panorama image, such as to drag the view horizontally and/or vertically as illustrated in panes 260s-260t relative to 260r, or to otherwise perform visual manipulations (e.g., zooming in or out). Such a simulated visualization panorama image may further be combined with other types of functionality described herein (e.g., to show selected lighting, window coverings, lighting fixtures, etc.), as well as to provide and use various types of user-selectable controls, although such combinations and controls are not illustrated in this example. It will be appreciated that other types of simulated visualizations may be displayed and manipulated in other manners in other embodiments.

While not illustrated in these examples, the GUI could have other forms in other embodiments, such as to have other user-selectable controls and user-modifiable controls (whether instead of or in addition to the illustrated controls), and/or to have particular controls be accessed and used in other manners. In addition, additional types of functionality related to end-user customizations for a floor plan may be provided in other embodiments. Various other changes to the GUI may be further made in other embodiments.

Various details have been provided with respect to FIGS. 2A-2R, but it will be appreciated that the provided details are non-exclusive examples included for illustrative purposes, and other embodiments may be performed in other manners without some or all such details.

In one further non-limiting example embodiment, the BIV system is used to provide a tool that helps partner entities who are builders of new construction houses (and optionally other buildings) in various manners, such as to generate more sales, streamline efficiencies at installation of interior finishes, and help their house buyers visualize builder-offered finishes in their specific floor plan in a user-friendly manner. In this example embodiment, each new housing community may use multiple floor plans for different building lots in the community, and the BIV system provides a tool for house buyer end-users to design their new house before it has been built. Each floor plan may have the following: associated architectural drawings, with measurements for each surface in the floor plan; defined interior finish products that are standard/included in the house (e.g., have a dollar value that is applied as a credit to any finishes that are upgraded); predetermined areas where those standard/included products will be installed in the house as part of the purchase price; etc.

In such an example embodiment, the BIV system allows new construction builders the ability to offer their house buyers a selection of flooring, countertop, wall tile, cabinets, wall color, hardware, and more to customize, with the BIV system walking a house buyer step-by-step through the customization selection process. For example, the builder may, after assigning a house buyer end-user to a house site in the community, provide the house buyer end-user with a link (e.g., via email) to access the BIV system (e.g., via a Web site provided by the BIV system), which the house buyer end-user uses to access the BIV system (e.g., to log into the BIV Web site) and be presented with a GUI displaying a floor plan and/or simulated room scene visualization that is specific to the house they are purchasing. For example, a dynamic floor plan may automatically slide out and illustrate to the house buyer the places within the house where they will be making customization selections, such as for a first step in a multi-step customization wizard (e.g., with different floor plans and/or floor plan areas highlighted for each step). As the buyer makes customization selections via the displayed GUI, they can view a simulated visualization of their selections from different angles/locations, such as by clicking on camera icons displayed on the dynamic floor plan that correspond to those angles/locations, or by selecting a camera in another manner (e.g., via a menu selection). Once all the customization selections have been made, the house buyer end-user(s) have the ability to toggle to various room scenes in one or more manners, such as by clicking on the dynamic floor plan, by using GUI tabs, etc. In at least some situations, the BIV system will further provide the ability to view one or more room scenes in additional manners, such as in 360° (e.g., can view the room with a virtual/augmented reality headset, such as an Oculus viewer), in simulated daylight or night time lighting, etc.

Thus, a house buyer end-user is guided through the customization process, such as via a series of categories from which to choose to design their house, and with the options within each category being customizable by the builder. Non-exclusive examples of such categories include the following: flooring, such as with sub-categories of tile, wood, LVP, etc., and optionally via a dropdown list of products displayed once the house buyer clicks on the category name (e.g., with each product name listed and its specifications viewable, such as by clicking on a magnifying glass on a displayed thumbnail of the product, and with a green check mark displayed on the individual product and on the category level once a selected product is displayed in the room scene); counters (such as via a dropdown list of countertop products displayed with the same types of functionality as noted above for flooring products); backsplashes (such as via a dropdown list of backsplash products displayed with the same types of functionality as noted above for flooring products); wall paint (such as via a dropdown list of wall paint colors displayed with the same types of functionality as noted above for flooring products); cabinets (such as via a dropdown list of cabinet colors/finishes displayed with the same types of functionality as noted above for flooring products); etc. The BIV system may provide a running aggregation of customization selections made so far (e.g., a running sales total that is generated in real-time with the selections, such as in less than a second, within a defined number of seconds, etc.). After all customization selections are made for a first step (and a displayed representation of the first step has a green check mark showing completion to the end-user), customization selections begin for the second step, which displays a different floor plan identifying where customization selections will be made in the house for the second step, and optionally carrying over visual information indicating the customization selections made from the first step. This process continues until all customization steps are performed, again providing a running aggregation of customization selections that have been made. Once all customization selections have been made for all defined interior surfaces and other defined interior elements, a complete estimate can be calculated (and printed, such as to show pricing and each room scene with selections made in each step), and customization selections may be contracted via the BIV system (e.g., a contract can be displayed and/or printed, signed digitally or manually by hand, and submitted to the builder), with a totals tab in the GUI providing the house buyer end-user with aggregation information (e.g., a total price) for each category, each product and each area. The BIV system may further display a house buyer end-user's budgeted amount along with an actual sales total, and optionally provide images in the galley of previous customization selections made by other end-users (e.g., others within the same community) that provide lower-cost customizations (e.g., to reduce or eliminate the difference between the budgeted amount and actual sales total)—alternatively, such a gallery of images with customization selection options could be displayed at any time throughout the multi-step process to assist the end-user in making customization selections. Since the floor plan dynamically displays customization selections as they are made, a final version of the floor plan is available once all customization selections have been made for all defined interior surfaces and other defined interior elements that shows all of those customizations.

The BIV system may provide further types of functionality in at least some embodiments, such as to create multiple alternative scenarios with different customization selections (e.g., by using ‘new’ and ‘copy’ buttons within the GUI), to share their customization selections with others (e.g., via email, to share the selections with a co-house buyer, family, friends, others already in the community, later prospective community members, etc.), to view previous scenarios created by themselves and/or by others (e.g., by a defined group of family and/or friends, and optionally without pricing information), to communicate with a designer to answer questions (e.g., via chat functionality within the GUI), etc.

Various details have been provided above with respect to the further non-limiting example embodiment, but it will be appreciated that the provided details are non-exclusive examples included for illustrative purposes and that other embodiments may be performed in other manners without some or all such details, and/or that any of the details discussed with respect to the further non-limiting example embodiment may be further included in the example embodiments discussed with respect to FIGS. 2A-2R and elsewhere herein.

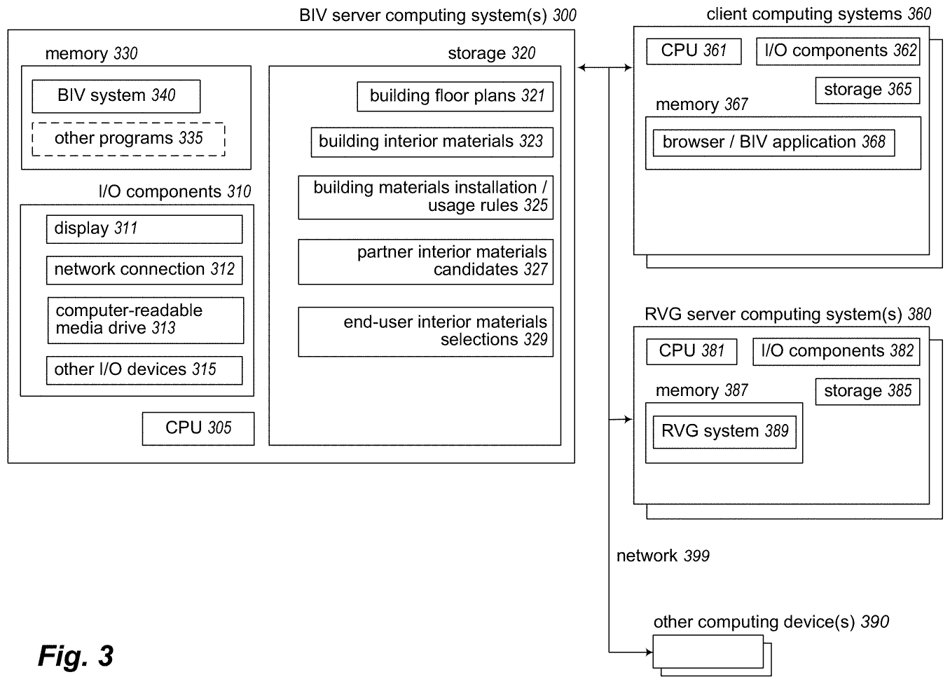

FIG. 3 is a block diagram illustrating an embodiment of one or more server computing systems 300 executing an implementation of a BIV system 340, one or more server computing systems 380 executing an implementation of an RVG system 389, and other computing systems and devices 360 and 390—the server computing system(s) and BIV and/or RVG systems may be implemented using a plurality of hardware components that form electronic circuits suitable for and configured to, when in combined operation, perform at least some of the techniques described herein. In the illustrated embodiment, each server computing system 300 includes one or more hardware central processing units (“CPUs”) or other hardware processors 305, various input/output (“I/O”) components 310, storage 320, and memory 330, with the illustrated I/O components including a display 311, a network connection 312, a computer-readable media drive 313, and other I/O devices 315 (e.g., keyboards, mice or other pointing devices, microphones, speakers, GPS receivers, etc.). Each server computing system 380 may have similar components, although only one or more hardware processors 381, memory 387, storage 385, and I/O components 382 are illustrated for the sake of brevity.

In the illustrated embodiment, an embodiment of the BIV system 340 executes in memory 330 of the server computing system(s) 300 in order to perform at least some of the described techniques, such as by using the processor(s) 305 to execute software instructions of the system 340 in a manner that configures the processor(s) 305 and computing system 300 to perform automated operations that implement those described techniques. The illustrated embodiment of the BIV system may include one or more components, not shown, to each perform portions of the functionality of the BIV system, and the memory may further optionally execute one or more other programs 335—as one specific example, a copy of the RVG system may execute as one of the other programs 335 in at least some embodiments, such as instead of or in addition to the RVG system 389 on the server computing system(s) 380. The BIV system 340 may further, during its operation, store and/or retrieve various types of data on storage 320 (e.g., in one or more databases or other data structures), such as information 321 related to building floor plans and corresponding included customizable elements, information 323 related building interior materials, information 325 related to building materials installation and usage rules, information 327 related to partner-specified candidates for and constraints related to building interior materials and other customizations, and information 329 related to end-user supplied information that includes customization selections for particular building floor plans and optionally additional associated information.

In addition, an embodiment of the RVG system 389 executes in memory 387 of the server computing system(s) 380 in the illustrated embodiment in order to perform automated operations related to generating and providing simulated building/room interior visualizations, such as by using the processor(s) 381 to execute software instructions of the system 389 in a manner that configures the processor(s) 381 and computing system 380 to perform such automated operations. The illustrated embodiment of the RVG system may include one or more components, not shown, to each perform portions of the functionality of the RVG system, and the computer memory 387 may further optionally execute one or more other programs (not shown). The RVG system 389 may further, during its operation, store and/or retrieve various types of data on storage 385 (e.g., in one or more databases or other data structures), although particular stored data is not shown in this example.

The server computing system(s) 300 (including executing BIV system 340) and other computing systems and devices 360, 380 and 390 (including executing RVG system 389) may communicate with each other and with other computing systems and devices in this illustrated embodiment via one or more networks 399 (e.g., the Internet, one or more cellular telephone networks, etc.). In other embodiments, some of the described functionality may be combined in less computing systems, such as to combine the BIV system 340 and the RVG system 389 in a single system or device (e.g. with the RVG system executing as one of the optional other programs 335 in memory 330).

The client computing systems 360 may, for example, be used by end-users, and/or partner entity users, and/or BIV system operator users, such as to use a browser 368 (or other application 368 specific to the BIV system) to interact with the BIV system and access corresponding functionality (e.g., via a Web site, not shown, that is provided by the BIV system). Some or all of the user client computing systems 390, server computing systems 380, and other computing systems 390 may similarly include some or all of the same types of components illustrated for server computing system 300. As one non-limiting example, the client computing systems 360 are each shown to include one or more hardware CPU(s) 361, I/O components 362, storage 365, and memory 367, with one or both of a browser and one or more client applications 368 executing within memory 367. While particular components are not illustrated for the other computing systems 390, it will be appreciated that they may include similar and/or additional components.

It will also be appreciated that computing systems 300, 370 and 380 and the other systems and devices included within FIG. 3 are merely illustrative and are not intended to limit the scope of the present invention. The systems and/or devices may instead each include multiple interacting computing systems or devices, and may be connected to other devices that are not specifically illustrated, including via Bluetooth communication or other direct communication, through one or more networks such as the Internet, via the Web, or via one or more private networks (e.g., mobile communication networks, etc.). More generally, a device or other computing system may comprise any combination of hardware that may interact and perform the described types of functionality, optionally when programmed or otherwise configured with particular software instructions and/or data structures, including without limitation desktop or other computers (e.g., tablets, slates, etc.), database servers, network storage devices and other network devices, smart phones and other cell phones, consumer electronics, wearable devices, digital music player devices, handheld gaming devices, PDAs, wireless phones, Internet appliances, and various other consumer products that include appropriate communication capabilities. In addition, the functionality provided by the illustrated systems 340 and/or 379 and/or 389 may in some embodiments each be distributed in various components, some of the described functionality of the systems 340 and/or 379 and/or 389 may not be provided, and/or other additional functionality may be provided.

It will also be appreciated that, while various items are illustrated as being stored in memory or on storage while being used, these items or portions of them may be transferred between memory and other storage devices for purposes of memory management and data integrity. Alternatively, in other embodiments some or all of the software components and/or systems may execute in memory on another device and communicate with the illustrated computing systems via inter-computer communication. Thus, in some embodiments, some or all of the described techniques may be performed by hardware means that include one or more processors and/or memory and/or storage when configured by one or more software programs (e.g., by the BIV system software 340 executing on server computing systems 300, by the RVG system software 389 executing on server computing systems 380, etc.) and/or data structures, such as by execution of software instructions of the one or more software programs and/or by storage of such software instructions and/or data structures, and such as to perform algorithms as described in the flow charts and other disclosure herein. Furthermore, in some embodiments, some or all of the systems and/or components may be implemented or provided in other manners, such as by consisting of one or more means that are implemented partially or fully in firmware and/or hardware (e.g., rather than as a means implemented in whole or in part by software instructions that configure a particular CPU or other processor), including, but not limited to, one or more application-specific integrated circuits (ASICs), standard integrated circuits, controllers (e.g., by executing appropriate instructions, and including microcontrollers and/or embedded controllers), field-programmable gate arrays (FPGAs), complex programmable logic devices (CPLDs), etc. Some or all of the components, systems and data structures may also be stored (e.g., as software instructions or structured data) on a non-transitory computer-readable storage mediums, such as a hard disk or flash drive or other non-volatile storage device, volatile or non-volatile memory (e.g., RAM or flash RAM), a network storage device, or a portable media article (e.g., a DVD disk, a CD disk, an optical disk, a flash memory device, etc.) to be read by an appropriate drive or via an appropriate connection. The systems, components and data structures may also in some embodiments be transmitted via generated data signals (e.g., as part of a carrier wave or other analog or digital propagated signal) on a variety of computer-readable transmission mediums, including wireless-based and wired/cable-based mediums, and may take a variety of forms (e.g., as part of a single or multiplexed analog signal, or as multiple discrete digital packets or frames). Such computer program products may also take other forms in other embodiments. Accordingly, embodiments of the present disclosure may be practiced with other computer system configurations.

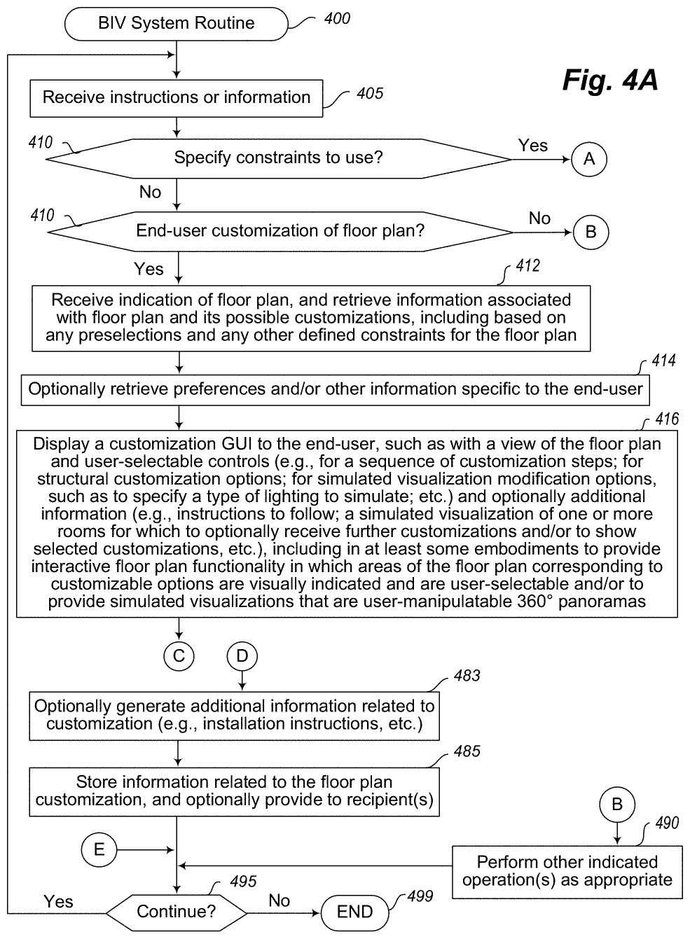

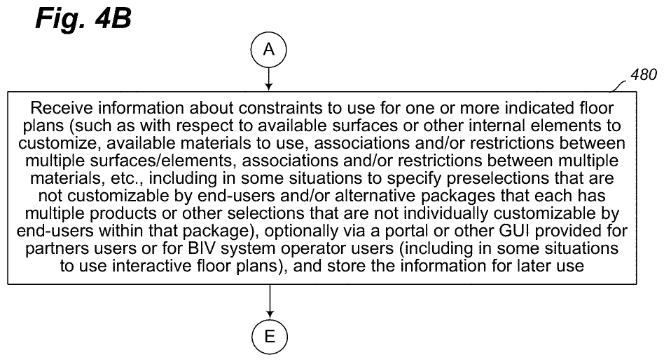

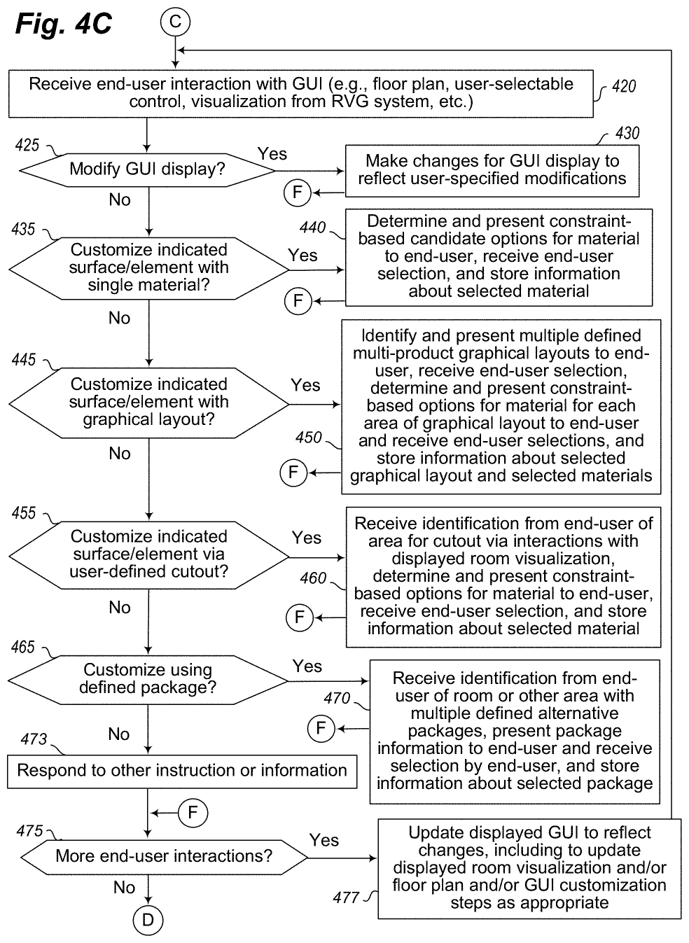

FIGS. 4A-4C illustrate an example flow diagram of an embodiment of a BIV System routine 400. The routine may be performed by, for example, the BIV system 140 of FIG. 1, the BIV system 340 of FIG. 3, and/or the BIV system described with respect to FIGS. 2A-2R and as otherwise described herein, such as to present simulated visualizations of building interior information in a user-customized manner, including to provide a GUI that an end-user may use to customize at least some aspects of a building's interior in accordance with defined constraints. In some embodiments, the customization activities for a building interior is performed for a planned building whose construction is not yet completed, while in other embodiments the customization activities may be performed for other types of buildings. In addition, while the illustrated embodiment performs customizations for the interior of a target building, it will be appreciated that other embodiments may perform similar techniques in other situations, including for non-building structures and/or for information external to one or more target buildings of interest.

The illustrated embodiment of the routine begins at block 405, where information or instructions are received. The routine then continues to block 410, where it determines if the instructions or information received in block 405 correspond to specifying constraints for the system to later use, such as constraints specified by a user representative of a partner entity and/or an operator user of the BIV system. If so, the routine continues to block 480 to receive information about candidate option constraints and/or other constraints to use for one or more indicated floor plans (or in other situations, for all floor plans), such as with respect to one or more of the following: surfaces or other internal elements that are available to be customized, materials that are available to be used for customizations of some or all such surfaces or other elements, associations and/or restrictions of one or more types between multiple indicated surfaces or other elements, etc. In at least some embodiments, the information is received via a GUI or other portal made available for partner entities or system operator users (including in some embodiments and situations to use interactive floor plan functionality), and the receiving of the information may occur over multiple interactions of one or more users with the BIV system, such as during one or more interaction sessions that occur over one or more periods of time. In some embodiments and situations, the constraint information that is specified may include one or more of the following: one or more preselections for particular floor plans and/or associated houses that are not customizable by end-users; one or more alternative groups/packages that each includes multiple products or other information to use together; etc. After the information is received in block 480, the routine stores the received constraint information for later use with the indicated floor plans.

If it is instead determined in block 410 that the instructions or information received in block 405 are not to specify constraints, the routine continues instead to block 410, where it determines if the information or instructions received in block 405 are from an end-user to initiate a customization of a floor plan. If not, the routine continues to block 490, and otherwise the routine continues to perform blocks 412-477 to interact with the end-user and obtain various customization-related information. In particular, in block 412, the routine receives an indication of the floor plan to be customized, and retrieves information associated with the floor plan and it's possible customizations, including based on any corresponding preselections and other defined constraints (e.g., as previously specified with respect to block 480), such as constraints defined specifically for the floor plan or for use with a group of floor plans that includes the indicated floor plan (e.g., for all floor plans). After block 412, the routine continues to block 414 where it optionally retrieves preferences and/or other information specific to the end-user, such as if the end-user has previously used the BIV system and specified such preferences or performed other interactions from which the system automatically determined such user-specific information (e.g., previous annotations specified by the end-user, such as for the indicated floor plans and/or for any floor plan).

In block 416, the routine then displays a customization-related GUI to the end-user, such as to display user-selectable controls together with a view of the floor plan and/or a simulated visualization of some or all of one or more rooms for which to optionally receive customizations from the end-user (e.g., a user-manipulatable panorama image that the end-user may adjust, such as for a 360° panorama image in which only a portion of the panorama image is displayed at any given time), optionally along with other associated information (e.g., instructions to follow, previously specified annotations, etc.), although in other embodiments the GUI may begin with one or more other types of displayed information. The user-selectable controls in the displayed GUI may, for example, correspond to a wizard or other sequence of customization steps for the end-user to perform as part of the customization activities, and in some embodiments and situations may be provided in part or in whole along with particular rooms or other items/elements of a displayed floor plan as part of providing interactive floor plan functionality. After block 416, the routine continues to block 420 to receive an end-user interaction with the GUI, such as via a selection of a displayed user-selectable control and/or an interaction with a room visualization generated by an RVG system and provided to the BIV system for inclusion within the GUI.

After block 420, the routine continues to block 425, where it determines if the end-user interaction was to modify a visual aspect of the displayed GUI (e.g., to scroll, zoom, change the color scheme, manipulate a displayed simulated visualization, etc.) in accordance with any defined constraints, and if so continues to block 430 to make one or more changes to the displayed GUI to reflect the user-specified modifications. If it was instead determined in block 425 that the end-user interaction was not to modify the displayed GUI, the routine continues instead to block 435 where it determines if the end-user interaction was an indication to customize an indicated surface or element within the building using a single material (e.g., a specific product using that material) or other single product. If so, the routine continues to block 440 to determine and present options to the end-user for the material/product to be used in accordance with any defined constraints, to receive a selection from the end-user of one of the materials/products, and to store information about the selected material/product for subsequent use. As with the interactions discussed with respect to block 480, the end-user interactions with the displayed GUI discussed in blocks 430-460 may include multiple actions by the end-user over one or more interaction sessions and periods of time (e.g., to start a particular customization one day, save intermediate results, and complete the customization on a different day).

If it is instead determined in block 435 that the end-user interaction of block 420 is not to customize an indicated surface or element with a single material or product, the routine continues instead to block 445, where it determines if the end-user interaction of block 420 is to customize an indicated surface or element using a multi-product or multi-material graphical layout (e.g., from a group of multiple predefined layouts). If so, the routine continues to block 450, where it identifies and presents multiple defined multi-product and/or multi-material graphical layouts to the end-user in accordance with any defined constraints, receives a selection by the end-user of one of the defined layouts to use, determines and presents options to the end-user of materials and/or products to use for each area or other part of the selected layout in accordance with any defined constraints, receives corresponding selections by the end-user of materials and/or products to use for the multiple areas/parts, and stores the information for subsequent use. If it is instead determined in block 445 that the end-user interaction of block 420 was not to customize an indicated surface or element with a defined layout, the routine continues instead to block 455 to determine if the end-user interaction of block 420 was instead to use a simulated visualization to specify a user-defined cutout or other further customization of an indicated area of a room. If so, the routine continues to block 460, where it receives, such as via one or more interactions of the end-user with a displayed room visualization and/or displayed floor plan, an identification from the end-user of an area with which to specify a cutout customization in accordance with any defined constraints, and then determines and presents options to the end-user of materials and/or products to use for the cutout customization in accordance with any defined constraints. The routine then receives a selection by the end-user of one or more materials/products to use for the cutout customization, and stores information about the identified area and the selected material(s)/product(s) for subsequent use.

If it is instead determined in block 455 that the end-user interaction of block 420 is not to customize an indicated surface or element using a user-defined cutout customization, the routine continues instead to block 465 to determine if the end-user interaction of block 420 was instead to perform customizations using one of multiple alternative defined groups/packages. If so, the routine continues to block 470, where it receives, such as via one or more interactions of the end-user with a displayed room visualization and/or displayed floor plan, an identification from the end-user of an area with which to select one of multiple alternative defined groups/packages in accordance with any defined constraints, and then determines and presents options to the end-user of such groups/packages, receives a selection by the end-user of one or more defined groups/packages to use, and stores information about the identified area and the selected defined group(s)/package(s) for subsequent use. If it is instead determined in block 465 that the end-user interaction of block 420 is not to perform customizations using one of multiple alternative defined groups/packages, the routine continues instead to block 473, where a response is performed to other instructions or information specified by the end-user via the interactions with the GUI. Such other interactions could include, for example, a selection made by the end-user to specify annotations for indicated locations on the floor plan or more generally to associate with the floor plan (such as to store for current and/or later display), a selection made by the end-user to exit the customization activities, or a selection made by the end-user that does not cause an immediate modification to the displayed GUI (e.g., to click or otherwise select a portion of the GUI that does not correspond to a user-selectable control).

After blocks 430, 440, 450, 460 or 473, the routine continues to block 475 to determine whether to perform more end-user interactions, such as until an instruction is received to terminate a current interaction session, or until the end-user completes a last of the customization activities. If it is determined that there are more end-user interactions to perform, the routine continues to block 477, where it updates the displayed GUI to reflect the changes made by the end-user in the last one or more end-user interactions, such as to update a displayed room visualization and/or displayed floor plan and/or a wizard or other sequence of steps corresponding to GUI customization activities to perform (e.g., to reflect completion of a step within the larger group of customization activities). After block 477, the routine returns to block 420 to receive a next end-user interaction with the updated GUI.

If it is instead determined in block 475 that there are no more end-user interactions to perform at the current time, the routine continues to block 483 to optionally generate additional information related to the customization activities, such as after all of the end-user customization activities are done for the floor plan being customized. Such additional information may include, for example, installation instructions corresponding to customizations specified by the end-user, other instructions to initiate activities corresponding to those customizations (e.g., to order materials for use in the customizations), etc. In block 485, the routine then stores information related to the floor plan customization, and optionally provides the customization information to one or more recipients (e.g., to a partner entity, to the end-user, etc.), such as when the end-user customizations are completed.

If it was instead determined in block 410 that the instructions or information received in block 405 are not to perform end-user customization of a floor plan, the routine continues to block 490 to perform one or more other indicated operations as appropriate. Such other operations may include, for example, receiving and storing information about floor plans for use in later end-user customizations, receiving and storing information about available materials and/or products for use in later end-user customizations, receiving and storing information about possible types of customization activities for use in later end-user customizations, receiving a room visualization and/or other related information from an RVG system, providing information about one or more previously defined customizations in response to a request (e.g., to a partner entity, to an RVG system, etc.), retrieving and using information about a partially completed set of customization activities by an end-user for a particular floor plan to allow those customization activities to continue, setting up an account for an end-user or otherwise obtaining information about preferences or related information for an end-user, setting up an account for a partner entity or otherwise receiving and storing information about preferences and other information about a partner entity, etc.

After blocks 480, 485 or 490, the routine continues to block 495, where it determines whether to continue, such as until an explicit indication to terminate is received. If it is determined to continue, the routine returns to block 405, and otherwise continues to block 499 and ends.

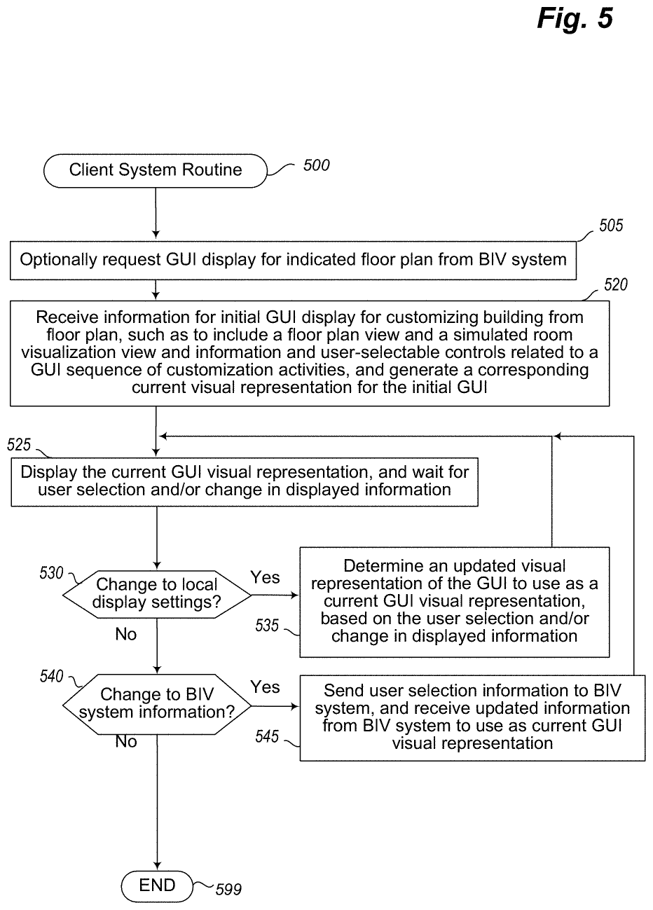

FIG. 5 illustrates an example flow diagram of an embodiment of a Client System routine 500. The routine may be performed by, for example, client computing systems 170-190 of FIG. 1, client computing systems 360 of FIG. 3, and/or client systems use by end-users as discussed with respect to FIGS. 2A-2R and as otherwise described herein, such as to display a provided GUI to a user of the client system and to receive and respond to various interactions of the user with the displayed GUI. It will be appreciated that a variety of types of devices may be used for such client systems, and that other types of user interactions with a GUI may be performed in other embodiments.

The illustrated routine 500 begins at block 505, where in some embodiments and situations it requests information from a BIV system and optionally from an RVG system to initiate a GUI display to a user of the client system (e.g., in response to a selection or other instruction by the user). In other embodiments, the client system may perform other types of activities without such request(s), such as to receive information pushed to it from the BIV system and/or an RVG system (e.g., in response to interactions of one or more users with the BIV system that cause the GUI display on the client system to be initiated). The routine then continues to block 520, where it receives information for an initial GUI display from the BIV system corresponding to customizing a floor plan of a building (and optionally from a separate RVG system, such as visualizations of one or more rooms for that floor plan or building). The received information may further include user-selectable controls and other aspects of the GUI, such as information about a wizard or other sequence of steps of customization activities to perform. In some embodiments and situations, the received information may be part of one or more Web pages that the client system renders, although in other embodiments other types of GUI displays may be used, including for the client system to construct a GUI page to display from underlying information received from the BIV system and optionally an RVG system. The routine then prepares a corresponding GUI page or other GUI visual representation for display on the client system.

After block 520, the routine continues to perform blocks 525-545 to enable the user of the client system to interact with the displayed GUI in various manners. In particular, the current GUI visual representation is displayed in block 525, where the routine then waits for an event to occur (e.g., a selection by the user; a change in the underlying information to be displayed, such as an update provided from the BIV and/or RVG systems; an expiration of a timer; etc.). After such an event occurs, the routine continues to block 530, where it determines if the event involves a local change to the displayed GUI (e.g., a change that can be performed by the client system without further interactions with one or more external systems), such as a user interaction to modify display settings, the receipt of new or changed information to display in the GUI, etc. If so, the routine continues to block 535, where it determines an updated visual representation of the GUI to use as a new current GUI visual representation based on the user selection and/or change in underlying information being displayed.

If it is instead determined in block 530 that the event in block 525 does not involve a local change to the displayed GUI, the routine continues instead to block 540, where it determines whether the event corresponds to a change in information stored by the BIV system (e.g., information specified by the user of the client system to be transferred to the BIV system), or involves other types of interaction with the BIV system (e.g., a request for new information to display). If so, the routine continues to block 545, where it sends a corresponding request and/or information to the BIV system, and receives updated information from the BIV system (and optionally the RVG system) to use as part of an updated GUI visual representation. After blocks 535 or 545, the routine returns to block 525, where the new current GUI visual representation is displayed, and the routine continues to wait for the next event

If it is instead determined in block 540 that the event in block 525 does not correspond to either a change in local display settings or the updated information to be provided to the BIV system, such as a request by the user to terminate the routine, the routine continues to block 599 and ends.

Aspects of the present disclosure are described herein with reference to flowchart illustrations and/or block diagrams of methods, apparatus (systems), and computer program products according to embodiments of the present disclosure. It will be appreciated that each block of the flowchart illustrations and/or block diagrams, and combinations of blocks in the flowchart illustrations and/or block diagrams, can be implemented by computer readable program instructions. It will be further appreciated that in some implementations the functionality provided by the routines discussed above may be provided in alternative ways, such as being split among more routines or consolidated into fewer routines. Similarly, in some implementations illustrated routines may provide more or less functionality than is described, such as when other illustrated routines instead lack or include such functionality respectively, or when the amount of functionality that is provided is altered. In addition, while various operations may be illustrated as being performed in a particular manner (e.g., in serial or in parallel, or synchronous or asynchronous) and/or in a particular order, in other implementations the operations may be performed in other orders and in other manners. Any data structures discussed above may also be structured in different manners, such as by having a single data structure split into multiple data structures and/or by having multiple data structures consolidated into a single data structure. Similarly, in some implementations illustrated data structures may store more or less information than is described, such as when other illustrated data structures instead lack or include such information respectively, or when the amount or types of information that is stored is altered.

From the foregoing it will be appreciated that, although specific embodiments have been described herein for purposes of illustration, various modifications may be made without deviating from the spirit and scope of the invention. Accordingly, the invention is not limited except as by corresponding claims and the elements recited by those claims. In addition, while certain aspects of the invention may be presented in certain claim forms at certain times, the inventors contemplate the various aspects of the invention in any available claim form. For example, while only some aspects of the invention may be recited as being embodied in a computer-readable medium at particular times, other aspects may likewise be so embodied.

What is claimed is:

1. A computer-implemented method comprising:
presenting, by one or more server computing systems implementing a building interior visualization system, and to an end-user using a client computing system, a graphical user interface (GUI) on a display of the client computing system that has one or more user-selectable controls to specify information for customizing interiors of multiple rooms of a house, wherein the presenting includes transmitting information over one or more computer networks to the client computing system for display in the GUI, wherein the GUI includes a first pane displaying a floor plan of the house that shows multiple locations within a first room from which visualizations of the first room may be generated, and wherein the GUI further includes a second pane shown simultaneously with the first pane and displaying a first visualization of the first room from one of the multiple locations;
receiving, by the one or more server computing systems, and via one or more first interactions of the end-user with the one or more user-selectable controls of the GUI, information about one or more interior customizations by the end-user of one or more first surfaces of the first room;
updating, by the one or more server computing systems, the second pane of the GUI to display a second visualization of the first room that is modified to show the one or more interior customizations for the one or more first surfaces of the first room;
presenting, by the one or more server computing systems, and in a third pane of the GUI, images of multiple predefined graphical layouts for use in customizing one or more second surfaces in a second room of the house, wherein each graphical layout specifies multiple areas on the one or more second surfaces in which different materials are to be added and indicates positioning of each of the multiple areas on the one or more second surfaces;
receiving, by the one or more server computing systems, and via one or more second interactions of the end-user with the one or more user-selectable controls of the GUI, one or more selections of one of the multiple predefined graphical layouts, and of multiple materials to be used in the multiple areas specified for the selected one graphical layout, such that each of the multiple materials is associated with at least one of the multiple areas specified for the selected one graphical layout;
updating, by the one or more server computing systems, the second pane of the GUI to display a third visualization that is of the second room and that shows the one or more second surfaces being customized to visually include the multiple materials in the multiple areas specified for the selected one graphical layout;
determining, by the one or more server computing systems, and for each of the multiple materials, one or more types of pieces of that material to install in the associated at least one area for that material, and a quantity of each of the one or more types of pieces of that material to fit a size and shape of the associated at least one area for that material, such that the multiple areas specified for the selected one graphical layout are filled in aggregate by the determined quantity for each of the one or more types of pieces of material for each of the multiple materials; and
providing, by the one or more server computing systems, additional information about customizations performed by the end-user via the GUI, including indications of the determined quantity for each of the one or more types of pieces of material for each of the multiple materials for use with the one or more second surfaces in the second room, and further including indications of one or more other materials for use in implementing the one or more interior customizations of the one or more first surfaces in the first room, to cause installation of the multiple materials in the second room of the building according to the selected one graphical layout, and to cause installation of the one or more other materials in the first room of the house as part of the one or more interior customizations.

2. The computer-implemented method of claim 1 further comprising:
receiving, by the client computing system, the information transmitted from the one or more server computing systems;
displaying, by the client computing system, and to the end-user, the GUI on the display of the client computing system, including simultaneously displaying the floor plan of the house in the first pane and the first visualization of the first room in the second pane;
transmitting, by the client computing system, first information to the one or more server computing systems from the one or more first interactions of the end-user;
displaying, by the client computing system, the second visualization of the first room in an updated second pane simultaneously with an updated version of the floor plan in the first pane, wherein the updated version of the floor plan shows visual indications of the one or more interior customizations of the one or more first surfaces;
receiving, by the client computing system, the images of the multiple predefined graphical layouts, and displaying the images in the third pane simultaneously with the second pane;
transmitting, by the client computing system, second information to the one or more server computing systems from the one or more second interactions of the end-user; and
displaying, by the client computing system, the third visualization of the second room in a further updated second pane simultaneously with a further updated version of the floor plan in the first pane, wherein the further updated version of the floor plan shows further visual indications of the multiple materials in the multiple areas on the one or more second surfaces of the second room that are specified for the selected one graphical layout.

3. The computer-implemented method of claim 2 further comprising:
receiving, over the one or more computer networks from an additional computing system executing a room visualization generation system, the first visualization and the second visualization and the third visualization; and
displaying, by the client computing system, and in the second pane, a sequence of the first visualization and the second visualization and the third visualization.

4. The computer-implemented method of claim 1 wherein the one or more first surfaces of the first room include at least one of a floor or a wall or a countertop, and wherein the receiving of the information about the one or more interior customizations further includes:
receiving, via interactions of the end-user with the displayed first visualization, a visual selection of a subset of the one or more first surfaces;
receiving, by the one or more server computing systems, a selection of a first material to include in the subset that is different from a second material in an area of the one or more first surfaces surrounding the subset, wherein the first material and the second material are each one of a type of tile or a type of wood or a type of vinyl covering;
determining, in response to the receiving of the visual selection of the subset and the receiving of the selection of the first material, a size and shape of the subset, and a category of material customizations to use for the subset that is one of a liner or a border or a frame, and one or more types of pieces of the first material to use for the subset, and a quantity of each of the one or more types of pieces of the first material in light of the size and shape;
and wherein the providing of the additional information further includes indicating the subset and the category and the one or more types of pieces of the first material and the determined quantity of each of the one or more types of pieces of the first material.

5. A computer-implemented method comprising:
presenting, by one or more computing systems, a graphical user interface (GUI) for virtually customizing an interior of a building, the GUI including a first pane displaying at least some of a floor plan of the building that shows at least one room of the building and that shows multiple locations within the at least one room from which visualizations of the at least one room may be generated, the GUI further including a second pane displaying a first visualization of the at least one room from one of the multiple locations simultaneously with the displaying of the at least some of the floor plan, and the GUI further including one or more user-selectable controls to specify information for the at least one room;
receiving, by the one or more computing systems, and via one or more interactions of a user with the one or more user-selectable controls of the GUI, information about one or more interior customizations by the user of one or more surfaces of the at least one room;
updating, by the one or more computing systems, the second pane of the GUI to display a second visualization of the at least one room that is modified to show the one or more interior customizations for the one or more surfaces of the at least one room; and
providing, by the one or more computing systems, information about one or more materials for use in implementing the one or more interior customizations, to cause installation of the one or more materials in the at least one room of the building as part of the one or more interior customizations.

6. The computer-implemented method of claim 5 further comprising receiving, by the one or more computing systems, a selection by the user via the GUI of one of the multiple locations shown in the first pane of the GUI, and wherein the updating of the second pane is further performed to display the second visualization from the selected one location.

7. The computer-implemented method of claim 5 wherein the one or more interior customizations include a selection by the user of a specified type of material to install on at least one surface in the at least one room, wherein the provided information about the one or more materials indicates the specified type of material, and wherein the method further comprises presenting, by the one or more computing systems and in a third pane of the GUI, multiple images of actual installations of the specified type of material in other buildings.

8. The computer-implemented method of claim 5 wherein the one or more interior customizations include a selection by the user of a specified type of material to install on at least one surface in the at least one room, wherein the provided information about the one or more materials indicates the specified type of material, and wherein the method further comprises presenting, by the one or more computing systems and in a third pane of the GUI, information to show multiple suggested customizations that each includes at least one further customization for the at least one room to use in combination with the one or more interior customizations for the one or more surfaces of the at least one room.

9. The computer-implemented method of claim 5 wherein multiple surfaces in multiple rooms of the building are associated together to share a type of material, wherein the one or more interior customizations by the user include a selection by the user of a specified type of material to install on at least one of the multiple surfaces in one of the multiple rooms, wherein the provided information about the one or more materials indicates the specified type of material, and wherein the method further comprises
determining, by the one or more computing systems, and in response to the selection by the user of the specified type of material to install on the at least one surface in the one room, that the multiple surfaces in the multiple rooms will all receive an installation of the specified type of material; and
updating, by the one or more computing systems, the first pane of the GUI to display an updated version of the floor plan having visual indications of the multiple surfaces in the multiple rooms sharing the specified type of material.

10. The computer-implemented method of claim 5 wherein the one or more interior customizations include a selection by the user of a specified type of material to install on at least one surface that is in the at least one room and that has a defined size and shape, and wherein the method further comprises:
determining, by the one or more computing systems, and in response to the one or more interactions of the user with the one or more user-selectable controls of the GUI, one or more types of pieces of the specified type of material to install on the at least one surface, a quantity of each of the one or more types of pieces in light of the defined size and shape, and one or more restrictions associated with installing the determined quantity of each of the one or more types of pieces of the specified type of material; and
presenting, by the one or more computing systems, and in response to the one or more interactions of the user with the one or more user-selectable controls of the GUI, the determined one or more restrictions to the user in the GUI,
and wherein the providing of the information about the one or more materials includes indicating the determined quantity of each of the one or more types of pieces of the specified type of material.

11. The computer-implemented method of claim 10 wherein the at least one surface includes at least one of a floor of the at least one room or a wall of the at least one room or a countertop of the at least one room, and wherein the specified type of material is at least one of a specified flooring material or a specified wall covering material or a specified type of countertop material.

12. The computer-implemented method of claim 10 further comprising:
determining, by the one or more computing systems, and in response to the one or more interactions of the user with the one or more user-selectable controls of the GUI, multiple additional options for customization of the at least one room that are compatible, according to constraints defined for the building, with installing the specified type of material on the at least one surface; and
presenting, by the one or more computing systems, additional information to the user via the GUI about the multiple additional options for customization.

13. The computer-implemented method of claim 12 wherein the determining of the multiple additional options for customization includes at least one of determining one or more additional types of materials to install with the specified type of material or determining one or more installation procedures to use for the installing of the specified type of material.

14. The computer-implemented method of claim 12 further comprising performing interactions, by the one or more computing systems, and before the presenting of the GUI, with one or more other users associated with the building to determine options for materials to use for interior customizations of the building, and wherein the one or more user-selectable controls included in the GUI enable the user to select from the determined options.

15. The computer-implemented method of claim 14 wherein the performing of the interactions with the one or more other users includes receiving constraints to implement that control interactions between multiple of the determined options.

16. The computer-implemented method of claim 12 further comprising performing interactions, by the one or more computing systems, and before the presenting of the GUI, with one or more other users associated with the building to define the constraints to use for the building.

17. The computer-implemented method of claim 10 wherein the one or more interior customizations include a selection by the user of a specified type of material to install on at least one surface in the at least one room, and wherein the method further comprises generating, by the one or more computing systems, instructions for installation of the one or more pieces of the specified type of material on the at least one surface in the at least one room, the instructions including textual instructions and visual representations of portions of the installation, and wherein the providing of the information about the one or more materials includes providing the generated instructions to enable the installation.

18. The computer-implemented method of claim 5 further comprising performing interactions, by the one or more computing systems and before the presenting of the GUI, with one or more other users associated with the building to determine preselections for a subset of multiple available interior customizations of the building, wherein the presenting of the GUI includes displaying information about at least one of the preselections in one or both of the displayed at least some floor plan or the displayed first visualization, wherein the one or more user-selectable controls included in the GUI do not enable the user to change the preselections for the subset of available interior customizations, and wherein the interactions of the user with the one or more user-selectable controls included in the GUI include the user specifying the one or more interior customizations from other of the available interior customizations that are not part of the subset.

19. The computer-implemented method of claim 5 further comprising performing interactions, by the one or more computing systems and before the presenting of the GUI, with one or more other users associated with the building to determine multiple alternative packages that each includes multiple interior customizations of the building to be used together, wherein the presenting of the GUI includes displaying information about at least some of the multiple alternative packages, and wherein the interactions of the user with the one or more user-selectable controls included in the GUI include the user selecting one of the multiple alternative packages to use, such that the multiple interior customizations included in the selected one alternative package are some or all of the one or more interior customizations by the user.

20. The computer-implemented method of claim 5 further comprising receiving, by the one or more computing systems, one or more indications to use simulated lighting from an indicated time of day in a simulated visualization of at least a portion of an interior of the building, and wherein at least one of the displaying of the first visualization in the second pane or displaying of the second visualization in the updated second pane includes using the simulated lighting for the indicated time of day in the first visualization or the second visualization.

21. The computer-implemented method of claim 20 wherein the one or more indications are to use one of simulated daylight lighting or simulated nighttime lighting and are specified by the user as part of the one or more interactions, and wherein the second visualization is a simulated visualization that uses the one of the simulated daylight lighting or the simulated nighttime lighting.

22. The computer-implemented method of claim 5 wherein the second visualization is a simulated visualization generated as a panorama image with 360 degrees of horizontal visual coverage around a vertical axis, wherein displaying of the second visualization in the updated second pane includes displaying a first subset of the panorama image that includes less than 360 degrees of horizontal visual coverage, and wherein the method further comprises displaying one or more second subsets of the panorama image that are different from the first subset in response to one or more manipulations by the user of the displayed first subset.

23. The computer-implemented method of claim 5 wherein the displaying of the at least some of the floor plan includes providing the displayed at least some floor plan in an interactive mode in which portions of the displayed at least some floor plan that are customizable by the user are visually highlighted and are selectable by the user, wherein the one or more interactions of the user include a selection by the user of one of the portions that are visually highlighted and a designation by the user of a customization for the selected one portion that is one of the one or more interior customizations.

24. The computer-implemented method of claim 23 further comprising, after the selection by the user of the one portion that is visually highlighted and the designation by the user of the customization for the selected one portion, updating the first pane of the GUI to display a modified version of the at least some floor plan with visual information to show the customization for the selected one portion.

25. The computer-implemented method of claim 5 wherein the one or more interactions of the user further include a selection by the user of one of multiple alternative structural options for the building, and wherein the method further comprises updating the first pane of the GUI to display a modified version of the at least some floor plan that includes information from the selected one alternative structural option for the building.

26. The computer-implemented method of claim 5 wherein the one or more interactions of the user further include one or more annotations specified by the user for at least a portion of the at least some floor plan, and wherein the method further comprises updating the first pane of the GUI to display the one or more annotations on the displayed at least some floor plan in a manner associated with the at least portion.

27. A non-transitory computer-readable medium having stored contents that cause one or more computing systems to perform automated operations including at least:
providing, by the one or more computing systems, information for display in a graphical user interface (GUI) that enables virtually customizing an interior of a building, wherein the GUI includes a display of at least some of a floor plan of the building that shows at least one room of the building and that has one or more locations within the at least one room from which visualizations of the at least one room may be generated, wherein the GUI further includes a display of a first visualization of the at least one room from one of the one or more locations, and wherein the GUI further includes one or more displayed user-selectable controls to specify information for the at least one room;
receiving, by the one or more computing systems, and via one or more interactions of a user with the one or more user-selectable controls of the GUI, information about one or more interior customizations by the user of one or more surfaces of the at least one room; and
updating, by the one or more computing systems, the GUI to display a second visualization of the of the at least one room that is modified to show the one or more interior customizations for the one or more surfaces of the at least one room.

28. The non-transitory computer-readable medium of claim 27 wherein the stored contents include software instructions that, when executed, program the one or more computing systems to further provide information about the one or more interior customizations to a builder of the building, to cause installation of one or more materials in the at least one room of the building as part of the one or more interior customizations.

29. The non-transitory computer-readable medium of claim 27 wherein the one or more computing systems include at least one computing system executing a building interior visualization system, wherein providing of the information for display includes transmitting the information over one or more computer networks to a client computing system being used by the user, and wherein display of the GUI occurs on the client computing system and includes displaying the at least some of the floor plan in a first part of the GUI simultaneously with displaying the first visualization in a second part of the GUI.

30. A system, comprising:
one or more hardware processors of one or more computing systems;
one or more display devices; and
one or more memories with stored instructions that, when executed by at least one of the one or more processors, cause the system to provide information for display in a graphical user interface (GUI) and to further perform automated operations that include at least:
providing visual representations in the GUI of multiple graphical layouts for use in customizing one or more surfaces in a room of a building, wherein each graphical layout specifies multiple areas on the one or more surfaces in which different materials are to be added and indicates positioning of each of the multiple areas on the one or more surfaces;
receiving, via one or more interactions of an end-user with the GUI, one or more selections of one of the multiple graphical layouts, and of multiple materials to be used in the multiple areas specified for the selected one graphical layout, such that each of the multiple materials is associated with at least one of the multiple areas specified for the selected one graphical layout;
providing further information to update the GUI to include a displayed visualization of at least part of the room that shows the one or more surfaces and is customized to visually include the multiple materials in the multiple areas specified for the selected one graphical layout;
determining, for each of the multiple materials, one or more types of pieces of that material to install in the associated at least one area for that material, and a quantity of each of the one or more types of pieces of that material to fit a size and shape of the associated at least one area for that material, such that the multiple areas specified for the selected one graphical layout are filled in aggregate by the determined quantity for each of the one or more types of pieces of material for each of the multiple materials; and
providing additional information about the determined quantity for each of the one or more types of pieces of material for each of the multiple materials, to cause installation of the multiple materials in the room of the building according to the selected one graphical layout.

31. The system of claim 30 wherein the stored instructions further cause the system to implement at least some functionality of a Building Interior Visualization system, wherein the multiple areas specified by at least one of the multiple graphical layouts are in different positions on the one or more surfaces than the multiple areas specified by at least one other of the multiple graphical layouts, wherein the visual representations in the GUI of the multiple graphical layouts include an image of each of the multiple graphical layouts that shows the multiple areas of that graphical layout in which the different materials are to be added, and wherein the automated operations further include, before the receiving of the one or more selections:
receiving information about one or more other selections by the end-user of one or more other graphical layouts that are different than the selected one graphical layout; and
providing, for each of the one or more other graphical layouts, other information to update the GUI to include an additional displayed visualization of at least part of the room that shows the one or more surfaces and is customized to visually include multiple materials in the multiple areas specified for the other graphical layout,
and wherein the providing of the additional information is performed in response to an indication by the end-user to use the one or more selections for the installation in the room of the building.

32. The system of claim 31 wherein the one or more computing systems include at least one server computing system that performs the implementing of the at least some functionality of the Building Interior Visualization system and further includes at least one client computing system that is in use by the end-user and displays the GUI, and wherein the providing of the further information to update the GUI is performed by the at least one server computing system and causes displaying, by the at least one client computing system, of the visualization of the at least part of the room.

33. The system of claim 30 wherein the automated operations further include:
determining, in response to the one or more selections, one or more restrictions to the end-user associated with installing the determined quantity for each of the one or more types of pieces of material for each of the multiple materials that include at least one cost; and
presenting information about the determined one or more restrictions to the end-user in the GUI.

34. The system of claim 30 wherein the one or more surfaces include at least one of a floor or a wall or a countertop, wherein the multiple materials include multiple of a first type of tile or a second type of tile or a third type of tile or a first type of wood or a second type of wood or a third type of wood or a first type of vinyl covering or a second type of vinyl covering or a third type of vinyl covering, and wherein the automated operations further include:
receiving information about a subset of the one or more surfaces that is specified in the displayed visualization by the end-user and that is different from the multiple areas specified in the selected one graphical layout, the information indicating at least a position of the subset and an additional material to include in the subset that is different from the multiple materials; and
determining, in response to the receiving of the information about the subset, a size and shape of the subset, and a category of material customizations to use for the subset that is one of a liner or a border or a frame, and one or more types of pieces of the additional material to use for the subset, and a quantity of each of the one or more types of pieces of the additional material in light of the size and shape;
and wherein the providing of the additional information further includes indicating the subset and the category and the one or more types of pieces of the additional material and the determined quantity of each of the one or more types of pieces of the additional material.
